(19) United States
(12) Patent Application Publication
(10) Pub. No.: US 2025/0210980 A1
(43) Pub. Date: Jun. 26, 2025

(54) Circuit Device

(71) Applicant: SEIKO EPSON CORPORATION, Tokyo (JP)

(72) Inventor: Masuhide IKEDA, Matsumoto (JP)

(21) Appl. No.: 18/989,732

(22) Filed: Dec. 20, 2024

(30) Foreign Application Priority Data
Dec. 21, 2023 (JP) 2023-215551

(51) Int. Cl. H02H 9/04; H03K 17/08

(52) U.S. Cl. CPC H02H 9/046; H03K 17/08

(57) ABSTRACT

A circuit device 10 includes a first terminal T1, a second terminal T2, a thyristor circuit 20, a voltage hold circuit 30, a trigger transistor TT, a predetermined capacitor CS, and a predetermined resistor RS. The thyristor circuit 20 is provided between the first terminal T1 and a node NA that is a first node. The voltage hold circuit 30 is provided between the node NA, which is the first node, and the second terminal T2. The trigger transistor TT causes a trigger current to flow through the thyristor circuit 20. The predetermined capacitor CS is provided between the first terminal T1 and a gate of the trigger transistor TT. The predetermined resistor RS is provided between the gate of the trigger transistor TT and the second terminal T2.

The present application is based on, and claims priority from JP Application Serial Number 2023-215551 filed Dec. 21, 2023, the disclosure of which is hereby incorporated by reference herein in its entirety.

### BACKGROUND

### 1. Technical Field

The present disclosure relates to a circuit device and the like.

### 2. Related Art

In the related art, a semiconductor device including various circuit devices such as a circuit device including an electrostatic protection circuit has been proposed. Considering the manufacturing efficiency, it is desirable that a plurality of circuit elements can be formed in one manufacturing process when manufacturing the semiconductor device. JP-A-2017-152462 discloses an electrostatic protection circuit device in which an inverter is used. JP-A-2017-108052 discloses a technique of simplifying a manufacturing process by forming a gate film of any transistor by a gate film forming step corresponding to a transistor having a small gate film thickness when forming different types of transistors on the same substrate.

For the electrostatic protection circuit device disclosed in JP-A-2017-152462, since a complementary metal-oxide-semiconductor (CMOS) with a high breakdown voltage is newly required and the gate film thickness cannot be made common for all the transistors, the technique disclosed in JP-A-2017-108052 cannot be applied. Therefore, a proposal for a circuit device for which an application range of a technique for simplifying the manufacturing process is wide is desired.

### SUMMARY

An aspect of the present disclosure relates to a circuit device including: a first terminal; a second terminal; a thyristor circuit provided between the first terminal and a first node; a voltage hold circuit provided between the first node and the second terminal; a trigger transistor configured to cause a trigger current to flow through the thyristor circuit; a capacitor provided between the first terminal and a gate of the trigger transistor; and a resistor provided between the gate of the trigger transistor and the second terminal.

### BRIEF DESCRIPTION OF THE DRAWINGS

FIG. 1 is a diagram illustrating a configuration example of a circuit device according to an embodiment.

FIG. 2 is a diagram illustrating a normal operation of the circuit device.

FIG. 3 is a diagram illustrating an example of a discharge path during static electricity application in the circuit device.

FIG. 4 is a diagram illustrating a node of a terminal of a thyristor.

FIG. 5A is a diagram schematically illustrating a cross section of the thyristor in the circuit device.

FIG. 5B is a diagram illustrating a plane of the thyristor in the circuit device.

FIG. 6A is a diagram schematically illustrating a cross section of a P-type DMOS.

FIG. 6B is a diagram schematically illustrating a plane of the P-type DMOS.

FIG. 7 is a diagram illustrating an example of a hold element.

FIG. 8A is a diagram schematically illustrating a cross section of a PMOS in the circuit device.

FIG. 8B is a diagram schematically illustrating a plane of the PMOS in the circuit device.

FIG. 9A is a diagram schematically illustrating a cross section of a PNP bipolar transistor in the circuit device.

FIG. 9B is a diagram schematically illustrating a plane of the PNP bipolar transistor in the circuit device.

FIG. 10A is a diagram schematically illustrating a cross section of a diode in the circuit device.

FIG. 10B is a diagram schematically illustrating a plane of the diode in the circuit device.

FIG. 11A is a diagram schematically illustrating a cross section of an NMOS in the circuit device.

FIG. 11B is a diagram schematically illustrating a plane of the NMOS in the circuit device.

FIG. 12A is a diagram schematically illustrating a cross section of an N-type DMOS in the circuit device.

FIG. 12B is a diagram schematically illustrating a plane of the N-type DMOS in the circuit device.

FIG. 13A is a diagram schematically illustrating a MOM capacitor in the circuit device.

FIG. 13B is a diagram schematically illustrating the MOM capacitor in the circuit device.

FIG. 13C is a diagram schematically illustrating the MOM capacitor in the circuit device.

FIG. 14 is a diagram illustrating another configuration example of the circuit device.

FIG. 15 is a diagram illustrating another configuration example of the circuit device.

FIG. 16 is a diagram illustrating another configuration example of the circuit device.

FIG. 17 is a diagram illustrating another configuration example of the circuit device.

FIG. 18 is a diagram illustrating another example of the discharge path during the static electricity application in the circuit device.

FIG. 19 is a diagram illustrating another configuration example of the circuit device.

FIG. 20 is a diagram illustrating another configuration example of the circuit device.

FIG. 21 is a diagram illustrating another configuration example of the circuit device.

FIG. 22 is a diagram illustrating another configuration example of the circuit device.

FIG. 23 is a diagram illustrating another example of the discharge path during the static electricity application in the circuit device.

FIG. 24 is a diagram illustrating another configuration example of the circuit device.

FIG. 25 is a diagram illustrating another example of the discharge path during the static electricity application in the circuit device.

FIG. 26 is a diagram illustrating another configuration example of the circuit device.

FIG. 27 is a diagram illustrating another example of the discharge path during the static electricity application in the circuit device.

FIG. 28 is a diagram illustrating another configuration example of the circuit device.

FIG. 29 is a diagram illustrating another example of the discharge path during the static electricity application in the circuit device.

### DESCRIPTION OF EMBODIMENTS

Hereinafter, a preferred embodiment according to the present disclosure will be described in detail. The embodiment described below does not unduly limit the contents described in the claims, and not all of the configurations described in the embodiment are essential components.

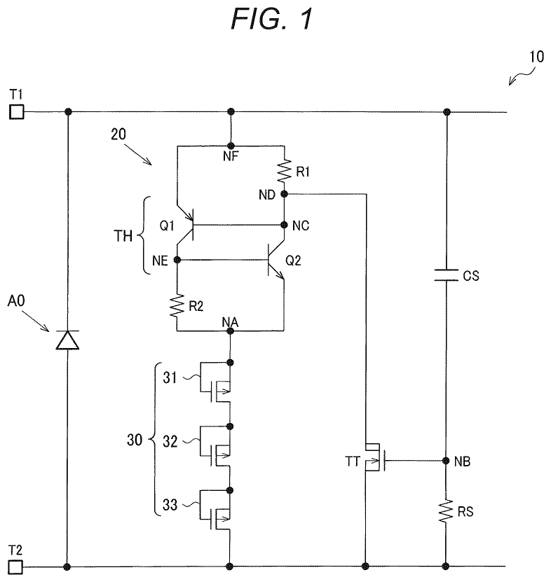

FIG. 1 is a configuration example of a circuit device 10 according to a technique of the embodiment. The circuit device 10 of the embodiment includes a first terminal T1, a second terminal T2, a thyristor circuit 20, a voltage hold circuit 30, a trigger transistor TT, a predetermined capacitor CS, and a predetermined resistor RS. The technique according to the embodiment can also be implemented as a semiconductor device. For example, a semiconductor device may be configured including the circuit device 10 illustrated in FIG. 1 and an internal circuit (not illustrated). Specifically, for example, when the semiconductor device is a motor driver IC, the internal circuit is a control circuit including a constant-voltage circuit, a pre-driver, an H-bridge circuit, or the like. Although not shown, the H-bridge circuit is a known circuit including, for example, a P-type double-diffused metal-oxide-semiconductor field-effect transistor (DMOS) and an N-type DMOS.

The circuit device 10 of the embodiment functions as an electrostatic protection circuit that protects the internal circuit from a surge when an ESD surge is applied. As will be described in detail later, when the voltage of the surge exceeds a trigger voltage, the trigger transistor TT causes a trigger current to flow and the thyristor TH provided in the thyristor circuit 20 is on, so that a current of the surge does not reach the internal circuit. During a period in which the applied voltage exceeds a hold voltage of the circuit device 10, the ON state of the thyristor TH is maintained. That is, the circuit device 10 is configured such that the hold voltage of the circuit device 10 of the embodiment is higher than a voltage for operating the internal circuit. This is because when not so, a signal of a voltage to be supplied to the internal circuit thereafter is absorbed by the circuit device 10 and the internal circuit does not function.

The first terminal T1 and the second terminal T2 are external coupling terminals of the circuit device 10, and are implemented as, for example, pads of the circuit device 10 or pads of a semiconductor device. In a region of the pad, a metal layer is exposed from a passivation film that is an insulating layer, and the exposed metal layer constitutes the pad that is the terminal of the circuit device 10. The first terminal T1 of the embodiment is one of a high-potential-side power supply terminal and a low-potential-side power supply terminal. The second terminal T2 is the other of the high-potential-side power supply terminal and the low-potential-side power supply terminal. In the following description, the first terminal T1 is described as a high-potential-side power supply terminal, and the second terminal T2 is described as a low-potential-side power supply terminal. The technique according to the embodiment relates to discharge in a direction from a power supply line coupled to the first terminal T1 to a power supply line coupled to the second terminal T2.

The circuit device 10 of the embodiment may further include a diode indicated by A0. The diode indicated by A0 is a diode whose forward direction is a direction from the power supply line coupled to the second terminal T2 toward the power supply line coupled to the first terminal T1. In this way, the diode can function as a discharge element on a discharge path in the direction from the power supply line coupled to the second terminal T2 to the power supply line coupled to the first terminal T1.

In order to make the description easy to understand, specific numerical values of voltages and the like may be illustrated, and are merely examples. In the following description, unless otherwise specified, the maximum operating voltage between the power supply line coupled to the first terminal T1 and the power supply line coupled to the second terminal T2 is assumed to be 24 V, and an absolute maximum rated voltage is assumed to be 40 V. That is, the maximum operating voltage of the internal circuit is 24 V. The voltage of the ESD surge applied to the first terminal T1 side is assumed to be 40 V. Further, it is assumed that the maximum operating voltage between a source and a drain of a p-channel metal-oxide-semiconductor field-effect transistor (PMOS) of the embodiment is 5.5 V, an absolute maximum rated voltage is 7 V, and a breakdown voltage and a hold voltage are 8 V. Further, it is assumed that the maximum operating voltage between a source and a drain of the DMOS of the embodiment is 24 V, an absolute maximum rated voltage is 40 V, the maximum operating voltage between a gate and the source is 5.5 V, and an absolute maximum rated voltage is 7 V. That is, in the DMOS provided in the semiconductor device of the embodiment, a breakdown voltage between the gate and the source is lower than a breakdown voltage between the source and the drain. This is because a process of forming a gate film is made common between the DMOS and the PMOS as in the technique disclosed in JP-A-2017-108052.

The thyristor circuit 20 includes the thyristor TH, a first resistor R1, and a second resistor R2. The configuration of the thyristor TH is equivalent to a circuit including a transistor Q1 that is a PNP-type bipolar transistor and a transistor Q2 that is an NPN-type bipolar transistor. In the following description, the thyristor TH will be described using the equivalent circuit. An emitter of the transistor Q1 is coupled to a node NF that is a node of the first terminal T1. A base of the transistor Q1 is coupled to a node NC that is a node of a collector of the transistor Q2. A collector of the transistor Q1 is coupled to a node NE that is a node of a base of the transistor Q2. An emitter of the transistor Q2 is coupled to a node NA. The first resistor R1 has one end coupled to the node NF and the other end coupled to the node NC. In other words, one end of the first resistor R1 is coupled to the first terminal T1, and the other end thereof is coupled to the collector of the transistor Q2. The resistor R2 has one end coupled to the node NE and the other end coupled to the node NA.

The voltage hold circuit 30 is provided between the node NA and the second terminal T2. That is, the voltage hold circuit 30 is coupled in series to the thyristor circuit 20 in the discharge path of the circuit device 10 functioning as an electrostatic protection circuit. Accordingly, a hold voltage of the circuit device 10 can be set to a desired voltage. Specifically, for example, when the internal circuit is operated at 24 V, the hold voltage of the circuit device 10 needs to be higher than 24 V. However, a hold voltage of the thyristor TH is only about 2 V, and after the application of the ESD surge occurs at the hold voltage of only the thyristor circuit 20, the thyristor TH remains in the ON state. Thereafter, even a voltage for operating the internal voltage is supplied to the semiconductor device, a current flows continuously in the thyristor TH and the internal circuit cannot operate. In this regard, by coupling the voltage hold circuit 30 and the thyristor circuit 20 in series as in the embodiment, a relationship is established that a total of the hold voltage of the thyristor TH and a hold voltage of the voltage hold circuit 30 becomes the hold voltage of the circuit device 10. Accordingly, the hold voltage of the circuit device 10 can be set to a desired voltage. Accordingly, for example, the circuit device 10 can function as an electrostatic protection circuit with respect to the internal circuit that is required to be supplied with a high voltage to drive a load. Even when an operating voltage of the internal circuit is not high, the circuit device 10 of the embodiment may be applied. In this case, the voltage hold circuit 30 may be configured such that the hold voltage thereof is low. That is, the circuit device 10 of the embodiment can be said to have a wide application range as an electrostatic protection circuit.

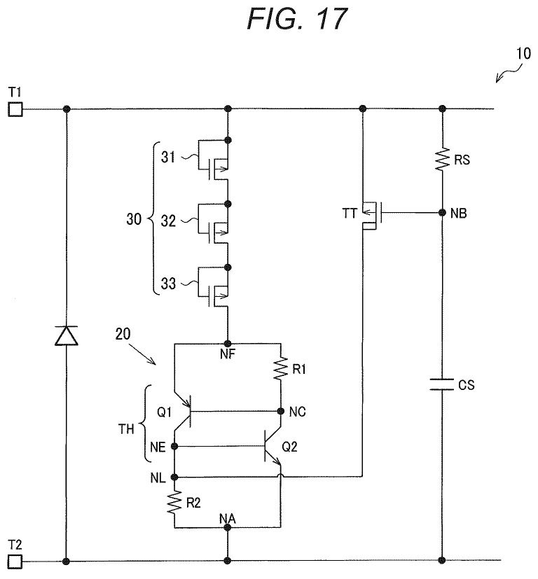

In the embodiment, as will be described later, the circuit device 10 functions as an electrostatic protection circuit, and the thyristor circuit 20 and the voltage hold circuit 30 are provided in series on the discharge path when the ESD surge is applied. In the embodiment, a coupling node between the thyristor circuit 20 and the voltage hold circuit 30 on the discharge path is referred to as a first node. Specifically, for example, in the circuit device 10 in FIG. 1, the node NA corresponds to the first node, and in the circuit device 10 in FIG. 17 to be described later, the node NF corresponds to the first node.

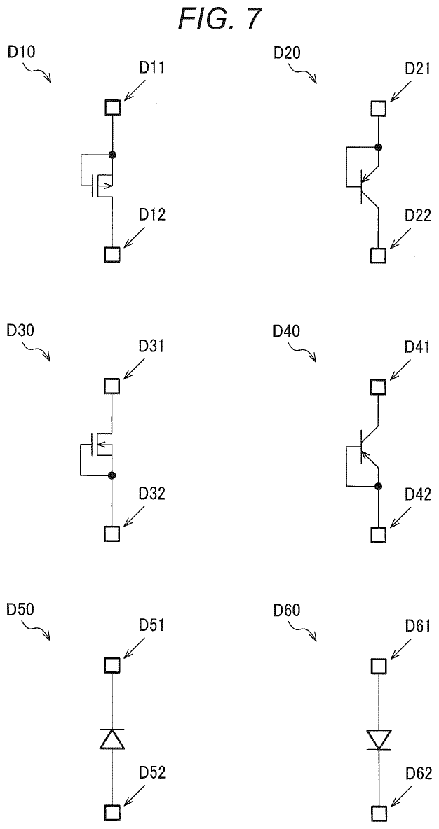

The voltage hold circuit 30 includes a hold element. Specifically, for example, in FIG. 1, the voltage hold circuit 30 includes a first hold element 31, a second hold element 32, and a third hold element 33. The number of the hold elements is not limited to three, and the voltage hold circuit 30 may generally include n hold elements. Although a source connected gate p-channel metal-oxide-semiconductor field-effect transistor (SGPMOS) is illustrated as the hold element illustrated in FIG. 1, the hold element that can be adopted in the embodiment is not limited to the SGPMOS, and details thereof will be described later with reference to FIG. 7. In FIG. 1, the first hold element 31, the second hold element 32, and the third hold element 33 are coupled in series. In this way, the hold voltage of the voltage hold circuit 30 can be set to a sum of hold voltages of the respective hold elements, whereby the hold voltage of the voltage hold circuit 30 can be set to a desired voltage. For example, as illustrated in FIG. 1, it is assumed that the first hold element 31, the second hold element 32, and the third hold element 33 are the same SGPMOS. In this case, since the hold voltage of the circuit device 10 is 26 V that is a total of 2 V, which is the hold voltage of the thyristor TH of the thyristor circuit 20, and 24 V (=8 V×3), which is the hold voltage of the voltage hold circuit 30, the hold voltage of the circuit device 10 is a voltage higher than 24 V that is the voltage for operating the internal circuit.

The trigger transistor TT constitutes a trigger circuit together with the predetermined capacitor CS and the predetermined resistor RS. The predetermined capacitor CS also constitutes an RC circuit together with the predetermined resistor RS. When an ESD surge is applied to the first terminal T1, the trigger circuit turns on the thyristor TH by a method described later. The trigger transistor TT in FIG. 1 is, for example, an N-type transistor, a drain thereof is coupled to the node ND that is a node at the other end of the first resistor R1, and a source thereof is coupled to the second terminal T2. In the example of the circuit device 10 described later with reference to FIG. 17, a P-type transistor can be adopted. Specifically, for example, in the case of protecting the internal circuit that drives a load, the trigger transistor TT may be implemented by, for example, an N-type DMOS. Similarly, in the circuit device 10 described later with reference to FIG. 17, a P-type DMOS may be used. In this way, the manufacturing process can be made common to the DMOS provided in the internal circuit.

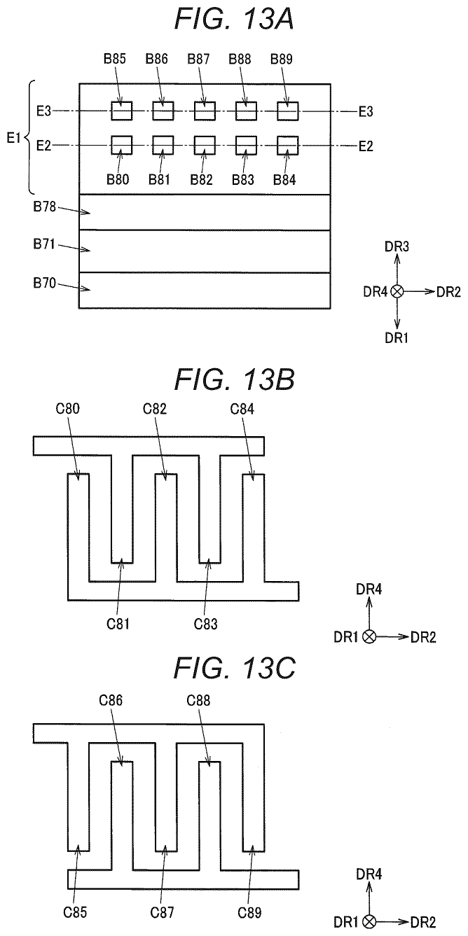

The predetermined capacitor CS is provided between the first terminal T1 and a node NB that is a gate node of the trigger transistor TT. The predetermined capacitor CS may be, for example, a MOM capacitor, and will be described later in detail with reference to FIG. 13. The predetermined resistor RS has one end coupled to the node NB and the other end coupled to the second terminal T2. In other words, the predetermined resistor RS is provided between the gate of the trigger transistor TT and the second terminal T2.

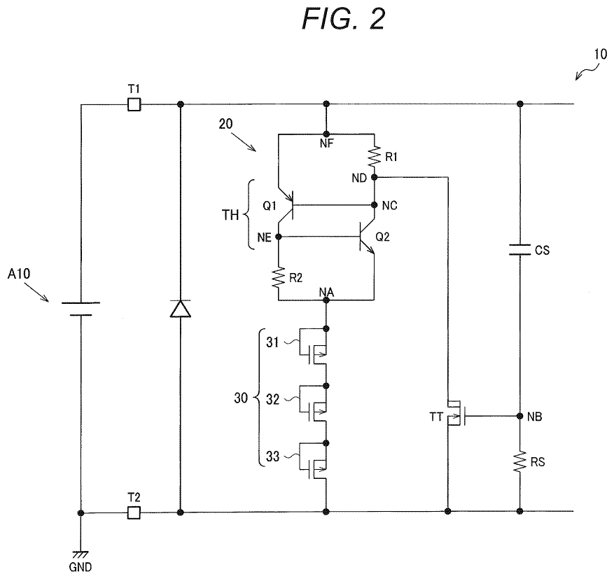

The semiconductor device including the circuit device 10 operates depending on an external power supply indicated by A10 in FIG. 2 during a normal operation. A power supply voltage of the external power supply indicated by A10 is 24 V. The second terminal T2 is coupled to the ground GND, and a ground voltage is 0 V.

Although a voltage of 24 V is supplied between the drain and the source of the trigger transistor TT, the trigger transistor TT is not destroyed since the trigger transistor TT is implemented by the above-described N-type DMOS. That is, a state is maintained in which the voltage on the drain side of the trigger transistor TT is 24 V that is equal to the voltage of the power supply line coupled to the first terminal T1, and the voltage on the source side of the trigger transistor TT is maintained at 0 V that is equal to the voltage of the power supply line coupled to the second terminal T2. During the normal operation, the predetermined resistor RS functions as a pull-down resistor, and a potential at the gate of the trigger transistor TT is 0 V equal to the voltage of the power supply line coupled to the second terminal T2. Therefore, there is no potential difference between the gate and the source of the trigger transistor TT, and the trigger transistor TT is off. Accordingly, the thyristor TH is also off. Each source of the SGPMOS of the first hold element 31 in the voltage hold circuit 30 is in a high impedance state. The same applies to the SGPMOS of the second hold element 32 and the third hold element 33. Accordingly, in FIG. 2, there is no path for a current to flow from the first terminal T1 to the second terminal T2.

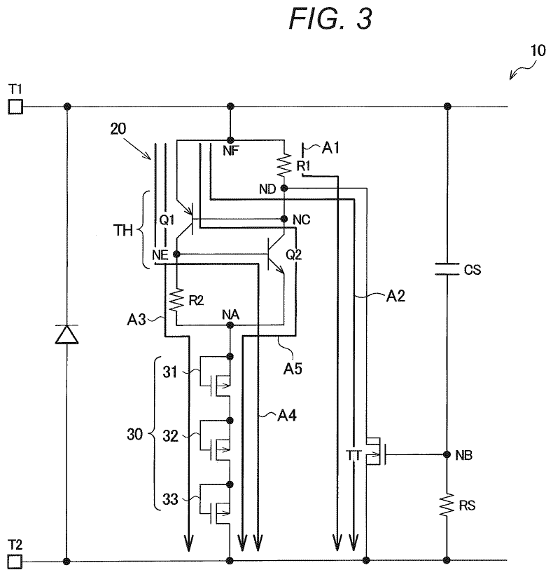

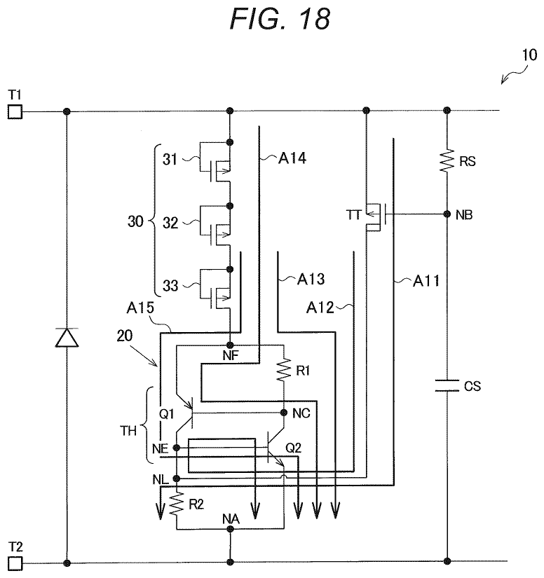

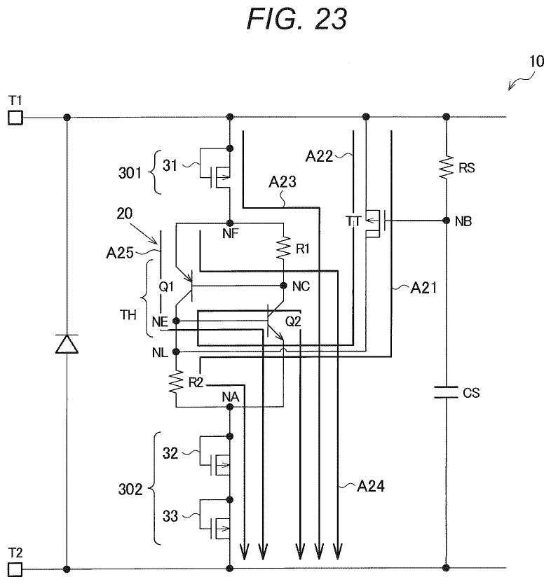

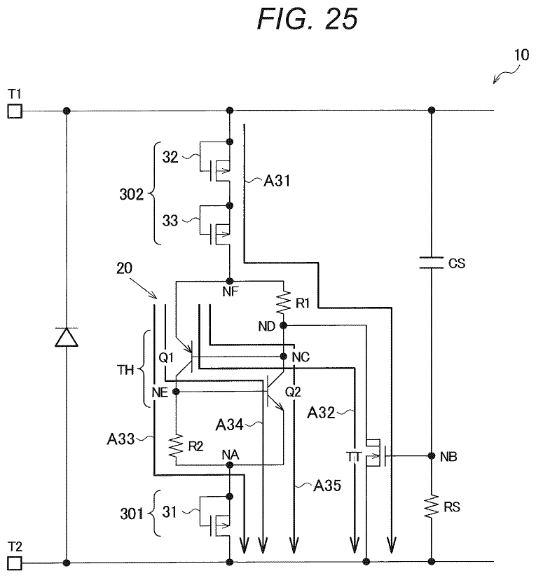

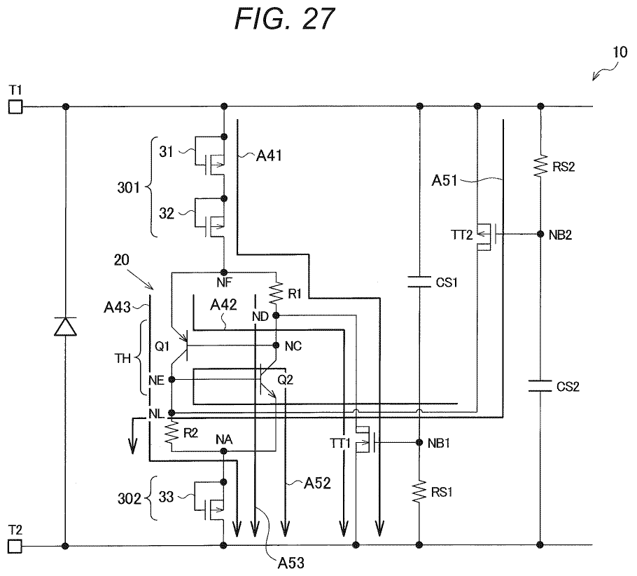

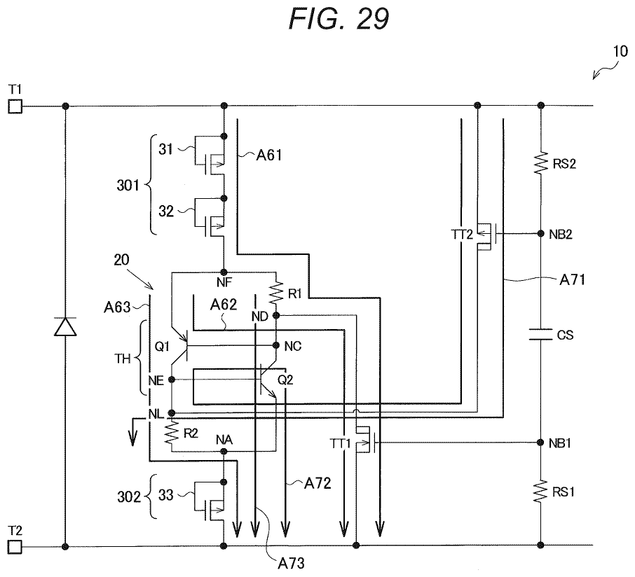

FIG. 3 illustrates an operation of the circuit device 10 occurring when an ESD surge is applied to the power supply line coupled to the first terminal T1. In FIG. 3, arrows indicated by A1, A2, A3, A4, and A5 are shown, and main current paths are schematically illustrated for easy understanding. For specific current paths, a supplementary description may be made. The same applies to arrows indicated by A11, A12, A13, A14, and A15 in FIG. 18, arrows indicated by A21, A22, A23, A24, and A25 in FIG. 23, arrows indicated by A31, A32, A33, A34, and A35 in FIG. 25, arrows indicated by A41, A42, A43, A51, A52, and A53 in FIG. 27, and arrows indicated by A61, A62, A63, A71, A72, and A73 in FIG. 29.

It is assumed that a potential of the first terminal T1 increases to, for example, 40 V. At this time, a potential of the node NB increases due to capacitive coupling of the predetermined capacitor CS. That is, a potential of the trigger transistor TT on the gate side increases. Accordingly, since a potential difference occurs between the gate and the source of the trigger transistor TT, the trigger transistor TT is turned on, and a current flows in a direction of the arrow indicated by A1. More accurately, the arrow indicated by A1 is directed in the order of the first terminal T1, the node NF, the first resistor R1, the node ND, the drain of the trigger transistor TT, the source of the trigger transistor TT, and the second terminal T2. Accordingly, a current flows through the first resistor R1, and the potential of the node ND coupled to the base of the transistor Q1 is lower than the potential of the first terminal T1 (node NF) coupled to the emitter of the transistor Q1. Accordingly, a current flows in a direction of the arrow indicated by A2. More accurately, the arrow indicated by A2 is directed in the order of the first terminal T1, the node NF, the emitter of the transistor Q1, the base of the transistor Q1, the node NC, the node ND, the drain of the trigger transistor TT, the source of the trigger transistor TT, and the second terminal T2. Accordingly, since a base current of the transistor Q1 flows, the transistor Q1 is on.

Accordingly, a current flows in a direction of the arrow indicated by A3. More accurately, the arrow indicated by A3 is directed in the order of the first terminal T1, the node NF, the emitter of the transistor Q1, the collector of the transistor Q1, the node NE, the second resistor R2, the node NA, the voltage hold circuit 30, and the second terminal T2. Accordingly, a current flows through the second resistor R2, and the potential of the node NE coupled to the base of the transistor Q2 is higher than the potential of the node NA coupled to the emitter of the transistor Q2. Accordingly, a current flows in a direction indicated by the arrow A4. More accurately, the arrow indicated by A4 is directed in the order of the first terminal T1, the node NF, the emitter of the transistor Q1, the collector of the transistor Q1, the node NE, the emitter of the transistor Q2, the node NA, the voltage hold circuit 30, and the second terminal T2. Accordingly, a base current of the transistor Q2 flows, and the transistor Q2 is on. Accordingly, a current flows in a direction of the arrow indicated by A5. More accurately, the arrow indicated by A5 is directed in the order of the first terminal T1, the node NF, the emitter of the transistor Q1, the base of the transistor Q1, the node NC, the collector of the transistor Q2, the emitter of the transistor Q2, the node NA, the voltage hold circuit 30, and the second terminal T2. That is, the thyristor TH is on.

Since the thyristor TH is on as described, the circuit device 10 including the thyristor circuit 20 operates as an electrostatic protection circuit. That is, an ESD surge current applied to the first terminal T1 flows toward the second terminal T2, thereby protecting the internal circuit (not illustrated).

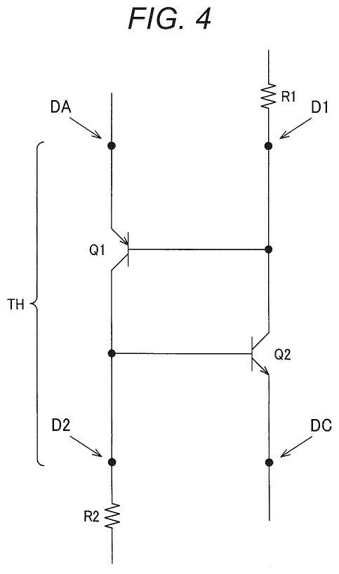

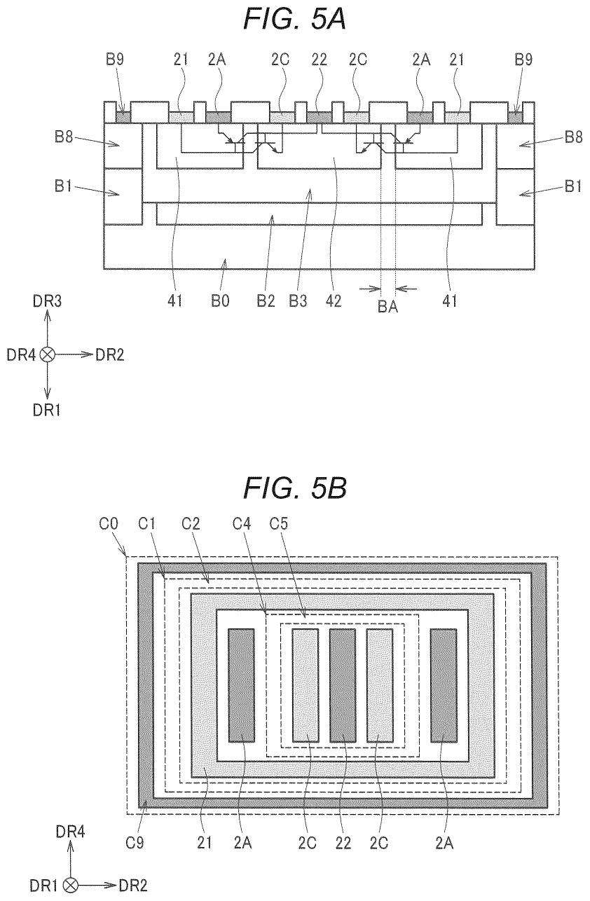

Referring to FIGS. 4, 5A and 5B, the thyristor TH of the embodiment will be described in more detail. FIG. 4 is a diagram illustrating a node coupled to the thyristor TH. As illustrated in FIG. 4, the thyristor TH is coupled to four nodes. In FIG. 4, a node indicated by D1 is a node of a first gate of the thyristor TH, a node indicated by D2 is a node of a second gate of the thyristor TH, a node indicated by DA is a node of an anode of the thyristor TH, and a node indicated by DC is a node of a cathode of the thyristor TH. The first gate corresponds to the base of the transistor Q1, and the second gate corresponds to the base of the transistor Q2. A state in which a current flows from the node indicated by DA to the node indicated by DC corresponds to the ON state of the thyristor TH.

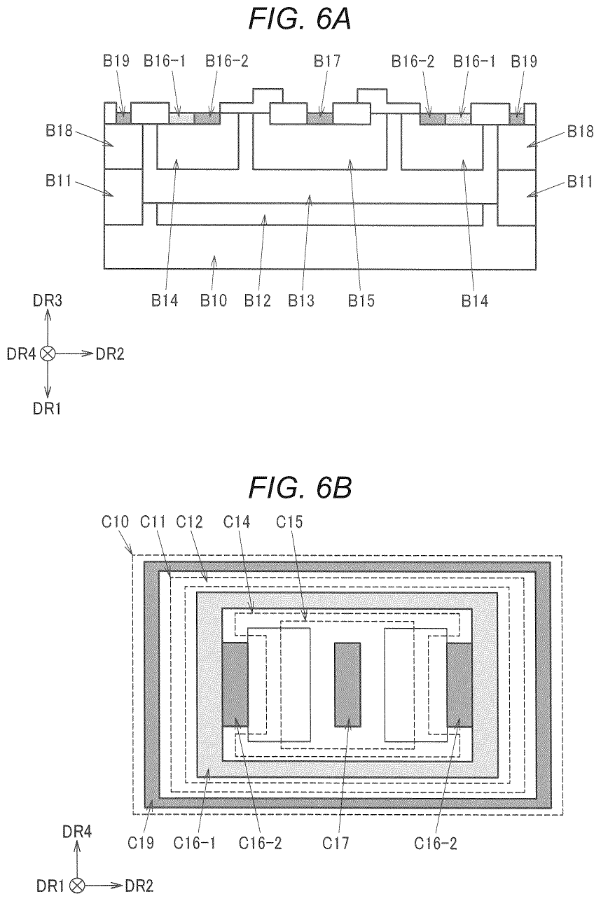

FIG. 5A is a schematic cross-sectional view of the thyristor TH of the embodiment. FIG. 5B is a schematic plan view of the thyristor TH of the embodiment. For the sake of convenience of description, FIG. 5A illustrates a schematic cross-sectional view at the time when a so-called front-end process is completed, and illustration of a wiring layer, an insulating layer, and the like formed in a so-called back-end process is omitted. The same applies to FIGS. 6A, 8A, 9A, 10A, 11A, and 12A. FIGS. 5A and 5B are schematic diagrams for the sake of convenience of description, and do not accurately indicate the dimensions and the like of each configuration. The same applies to FIGS. 6A, 6B, 8A, 8B, 9A, 9B, 10A, 10B, 11A, 11B, 12A, and 12B.

A second conductivity type well indicated by B1 and a first conductivity type well indicated by B2 are formed with respect to a base substrate indicated by B0 in FIG. 5A. The base substrate is, for example, a so-called P-type substrate that is a silicon substrate containing an impurity of a second conductivity type such as boron. Examples of impurities of a first conductivity type described later include phosphorus. A region indicated by a dotted frame of C0 in FIG. 5B corresponds to a region of the base substrate indicated by B0 in FIG. 5A. Further, in FIG. 5B, a ring-shaped region between the dotted frame of C0 and a dotted frame of C1 corresponds to a region of the second conductivity type well indicated by B1 in FIG. 5A. Further, in FIG. 5B, a region indicated by a dotted frame of C2 corresponds to a region of the first conductivity type well indicated by B2 in FIG. 5A.

The well of the embodiment refers to a region in which an impurity is implanted and which is provided below a circuit element or another well. The well of the embodiment may be implemented by a so-called buried diffusion layer in which an N-type impurity or a P-type impurity is implanted by ion implantation or the like and thermally diffused under predetermined conditions, or may be implemented by a so-called epitaxial layer formed by a vapor phase growth method.

In the embodiment, the first conductivity type refers to one of positive and negative conductivity types, and the second conductivity type refers to the other of the positive and negative conductivity types. For example, the first conductivity type well indicated by B2 in FIG. 5A can also be referred to as an N-type well, and the second conductivity type well indicated by B1 in FIG. 5A can also be referred to as a P-type well. Hereinafter, for convenience of description, the first conductivity type well, a first conductivity type transistor, and the like are described as an N-type well, an N-type transistor, and the like. Similarly, the second conductivity type well, a second conductivity type transistor, and the like are described as a P-type well, a P-type transistor, and the like.

In FIG. 5A, a downward direction with respect to a plane including the base substrate is defined as a first direction DR1. The downward direction is a direction directing from a front surface toward a back surface in a thickness direction of the base substrate. A direction opposite to the first direction DR1, that is, an upward direction with respect to the plane including the base substrate is defined as a third direction DR3. That is, the first direction DR1 and the third direction DR3 are orthogonal to the base substrate. A direction, which extends along the plane including the base substrate and in which a cathode region 2C and a second gate region 22 to be described later are alternately arranged, is defined as a second direction DR2. A direction, which extends along the plane including the base substrate and is orthogonal to the second direction DR2, is defined as a fourth direction DR4. The same applies to FIGS. 6A, 7A, 8A, 9A, 10A, 11A, 12A, and 13A.

An N-type well indicated by B3 in FIG. 5A is formed and a P-type well indicated by B8 in FIG. 5A is also formed. In FIG. 5B, the region indicated by the dotted frame of C1 corresponds to a region of the N-type well indicated by B3 in FIG. 5A. Further, in FIG. 5B, the ring-shaped region between the dotted frame of C0 and the dotted frame of C1 corresponds to a region of the P-type well indicated by B8 in FIG. 5A.

In FIG. 5A, a first well 41, which is an N-type well, and a second well 42, which is a P-type well, are provided at the N-type well indicated by B3. In FIG. 5B, a ring-shaped region between the dotted frame of C2 and a dotted frame of C4 corresponds to a region of the first well 41 in FIG. 5A. Further, in FIG. 5B, a region indicated by a dotted frame of C5 corresponds to a region of the second well 42 in FIG. 5A.

After the P-type well indicated by B8, the first well 41, and the second well 42 are formed and planarized, a layer having a pattern of the N-type impurity diffusion region and a layer having a pattern of the P-type impurity diffusion region are formed. The pattern of the N-type impurity diffusion region includes a pattern of a first gate region 21 and a pattern of the cathode region 2C. The pattern of the P-type impurity diffusion region includes a pattern of the second gate region 22, a pattern of an anode region 2A, and a pattern of a region indicated by B9.

The first gate region 21 is an impurity diffusion region doped with an N-type impurity element and is provided at the first well 41. The first gate region 21 is coupled to the node indicated by D1 in FIG. 4 via a contact (not illustrated). That is, the first gate region 21 is coupled to the first terminal T1 via the first resistor R1. In the plan view of FIG. 5B, the first gate region 21 is provided in a ring shape surrounding the anode region 2A, the second gate region 22, and the cathode region 2C.

The anode region 2A is an impurity diffusion region doped with a P-type impurity element, and is provided at the first well 41. The anode region 2A is coupled to the node indicated by DA in FIG. 4 via a contact (not illustrated). That is, the anode region 2A is coupled to the first terminal T1.

The second gate region 22 is an impurity diffusion region doped with a P-type impurity element, and is provided at the second well 42. The second gate region 22 is coupled to the node indicated by D2 in FIG. 4 via a contact (not illustrated). That is, the second gate region 22 is coupled to the second terminal T2 via the second resistor R2.

The cathode region 2C is an impurity diffusion region doped with an N-type impurity element, and is provided at the second well 42. The cathode region 2C is coupled to the node indicated by DC in FIG. 4 via a contact (not illustrated). That is, the cathode region 2C is coupled to the second terminal T2.

Here, the configuration including the P-type anode region 2A, the N-type first well 41, and the P-type second well 42 can be regarded as a PNP-type bipolar transistor, that is, the transistor Q1, in which the anode region 2A is an emitter, the first well 41 is a base, and the second well 42 is a collector. The configuration including the N-type first well 41, the P-type second well 42, and the N-type cathode region 2C can be regarded as an NPN-type bipolar transistor, that is, the transistor Q2, in which the cathode region 2C is the emitter, the second well 42 is the base, and the first well 41 is the collector. In this way, with the anode region 2A, the first well 41, the second well 42, and the cathode region 2C illustrated in the schematic cross-sectional view of FIG. 5A, functions of the thyristor TH as a PNPN thyristor can be implemented.

The region indicated by B9 in FIG. 5A is an impurity diffusion region doped with a P-type impurity element, and is provided at the P-type well indicated by B8. In the plan view of FIG. 5B, a region provided in a ring shape indicated by C9 corresponds to the region indicated by B9 in FIG. 5A.

Further, as indicated by BA in FIG. 5A, the breakdown voltage of the thyristor TH depends on a space between the first well 41 and the second well 42. For example, when the space between the first well 41 and the second well 42 is widened, the breakdown voltage of the thyristor TH can be increased.

FIG. 6A is a schematic cross-sectional view of the above-described P-type DMOS, and FIG. 6B is a schematic plan view of the P-type DMOS. B10 in FIG. 6A indicates a base substrate, and corresponds to a region indicated by a dotted frame of C10 in FIG. 6B. In FIG. 6A, a P-type well indicated by B11 and an N-type well indicated by B12 are formed at the base substrate indicated by B10. Further, in FIG. 6B, a ring-shaped region between the dotted frame of C10 and a dotted frame of C11 corresponds to a region of the P-type well indicated by B11 in FIG. 6A. Further, in FIG. 6B, a region indicated by a dotted frame of C12 corresponds to a region of the N-type well indicated by B12 in FIG. 6A. An N-type well indicated by B13 in FIG. 6A is formed and a P-type well indicated by B18 is also formed. In FIG. 6B, a region indicated by the dotted frame of C11 corresponds to a region of the N-type well indicated by B13 in FIG. 6A. Further, in FIG. 6B, the ring-shaped region between the dotted frame of C10 and the dotted frame of C11 corresponds to a region of the P-type well indicated by B18 in FIG. 6A. In FIG. 6A, an N-type well indicated by B14 and a P-type well indicated by B15 are provided at the N-type well indicated by B13. In FIG. 6B, a ring-shaped region between the dotted frame of C12 and a dotted frame of C14 corresponds to a region of the N-type well indicated by B14 in FIG. 6A. Further, in FIG. 6B, a region indicated by a dotted frame of C15 corresponds to a region of the P-type well indicated by B15 in FIG. 6A.

After the N-type well indicated by B14, the P-type well indicated by B15, and the P-type well indicated by B18 are formed and planarized, a layer having a pattern of an N-type impurity diffusion region and a layer having a pattern of a P-type impurity diffusion region are formed. The pattern of the N-type impurity diffusion region includes a pattern of a region B16-1 in FIG. 6A. The pattern of the P-type impurity diffusion region includes a pattern of a region indicated by B16-2 in FIG. 6A, a pattern of a region indicated by B17, and a pattern of a region indicated by B19.

The N-type impurity diffusion region indicated by B16-1 in FIG. 6A is formed in a ring shape surrounding a region indicated by C16-2 and a region indicated by C17, as indicated by C16-1 in FIG. 6B. The P-type impurity diffusion region indicated by B16-2 in FIG. 6A corresponds to the region indicated by B16-2 in the plan view of FIG. 6B, and the P-type impurity diffusion region indicated by B17 in FIG. 6A corresponds to the region indicated by C17 in the plan view of FIG. 6B. The P-type impurity diffusion region indicated by B19 in FIG. 6A corresponds to a region provided in a ring shape indicated by C19 in the plan view of FIG. 6B. In FIG. 6A, the N-type impurity diffusion region indicated by B16-1 is a region for setting the potential of the substrate, the P-type impurity diffusion region indicated by B16-2 is coupled to a node of a source, and the P-type impurity diffusion region indicated by B17 is coupled to a node of a drain.

Comparing FIGS. 5A and 5B with FIGS. 6A and 6B, the regions indicated by B0, B1, B2, B3, and B8 in FIG. 5A are common to the regions indicated by B10, B11, B12, B13, and B18 in FIG. 6A, the region of the first well 41 in FIG. 5A is common to the region of B14 in FIG. 6A, and the region of the second well 42 in FIG. 5A is common to the region of B15 in FIG. 6A. That is, in the thyristor TH of the embodiment, the regions indicated by B0, B1, B2, B3, and B8 in FIG. 5A, the region of the first well 41, and the region of the second well 42 in FIG. 5A are formed by the same manufacturing process as that of the P-type DMOS illustrated in FIG. 6A.

A pattern formation process for the first gate region 21 and the cathode region 2C in FIG. 5A is common to a pattern formation process and the manufacturing process for the N-type impurity diffusion region indicated by B16-1 in FIG. 6A. In other words, the N-type impurity diffusion region functioning as the first gate region 21 and the cathode region 2C of the thyristor TH illustrated in FIG. 5A is formed by the same manufacturing process as the N-type impurity diffusion region of the substrate of the P-type DMOS illustrated in FIG. 6A. Similarly, a pattern formation process for the second gate region 22 and the anode region 2A in FIG. 5A is common to a pattern formation process and the manufacturing process for the P-type impurity diffusion region indicated by B16-2 and B17 in FIG. 6A. In other words, the second gate region 22 and the anode region 2A of the thyristor TH illustrated in FIG. 5A are formed by the same manufacturing process as the N-type impurity diffusion region of the source and drain of the P-type DMOS illustrated in FIG. 6A. As described above, the thyristor TH of the embodiment can be manufactured by a process common to the P-type DMOS. As will be described later, elements other than the thyristor TH provided in the circuit device 10 of the embodiment can also be manufactured by a process common to the P-type DMOS.

As described above, the circuit device 10 of the embodiment includes the first terminal T1, the second terminal T2, the thyristor circuit 20, the voltage hold circuit 30, the trigger transistor TT, the predetermined capacitor CS, and the predetermined resistor RS. The thyristor circuit 20 is provided between the first terminal T1 and the node NA that is the first node. The voltage hold circuit 30 is provided between the node NA, which is the first node, and the second terminal T2. The trigger transistor TT causes a trigger current to flow through the thyristor circuit 20. The predetermined capacitor CS is provided between the first terminal T1 and the gate of the trigger transistor TT. The predetermined resistor RS is provided between the gate of the trigger transistor TT and the second terminal T2.

As described above, since the circuit device 10 of the embodiment includes the first terminal T1, the second terminal T2, the thyristor circuit 20, the trigger transistor TT, the predetermined capacitor CS, and the predetermined resistor RS, the circuit device 10 can operate as an electrostatic protection circuit including the trigger circuit that causes a trigger current to flow through the thyristor circuit 20. Further, since the thyristor circuit 20 and the voltage hold circuit 30 are provided in series between the first terminal T1 and the second terminal T2, the hold voltage between the power supply line including the first terminal T1 and the power supply line including the second terminal T2 can be set to a desired voltage. Accordingly, it is possible to construct an electrostatic protection circuit in which the voltage range for driving the internal circuit between the first terminal T1 and the second terminal T2 is wide and for which the manufacturing process can be made common. In the circuit device disclosed in JP-A-2017-152462, it is difficult to make the gate film thickness common to other devices since a CMOS having a high gate breakdown voltage is required. In contrast, in the circuit device 10 of the embodiment, since a transistor having a high gate breakdown voltage is unnecessary, the manufacturing process can be made common and an increase in the manufacturing cost can be prevented.

In the circuit device 10 of the embodiment, the trigger transistor TT may be a transistor having a DMOS structure. In this way, the trigger transistor TT can be provided in the circuit device 10 that is driven at a high voltage. As described above, in the embodiment, although the DMOS serving as the trigger transistor TT needs to increase the breakdown voltage between the source and the drain, the breakdown voltage between the gate and the source can be made common to other transistors. Accordingly, in the circuit device 10 driven at a high voltage, the manufacturing processes for the DMOS and the other elements can be made common. Accordingly, it is possible to prevent an increase in manufacturing cost of the semiconductor device driven at a high voltage.

In the circuit device 10 of the embodiment, the trigger transistor TT is a transistor having the DMOS structure of a first conductivity type or a transistor having the DMOS structure of a second conductivity type, and the anode region 2A of the thyristor circuit 20 and the source region and the drain region of the DMOS structure of the second conductivity type may be second conductivity type impurity diffusion regions of the same layer. In this way, the anode region 2A can be formed together with the DMOS of the second conductivity type.

In the circuit device 10 of the embodiment, the cathode region 2C of the thyristor circuit 20 and the region for setting the potential of the substrate of the second conductivity type transistor having the DMOS structure may be the same first conductivity type impurity diffusion region. In this way, the cathode region 2C can be formed together with the DMOS of the second conductivity type.

In the circuit device 10 of the embodiment, the first terminal T1 may be one of the high-potential-side power supply terminal and the low-potential-side power supply terminal, and the second terminal T2 may be the other of the high-potential-side power supply terminal and the low-potential-side power supply terminal. In this way, the thyristor circuit 20 and the voltage hold circuit 30 can be arranged between the high-potential-side power supply terminal and the low-potential-side power supply terminal.

In the circuit device 10 of the embodiment, the thyristor circuit 20 may include the anode region 2A of the second conductivity type, the cathode region 2C of the first conductivity type, the first gate region 21 of the first conductivity type, and the second gate region 22 of the second conductivity type. The anode region 2A of the second conductivity type may be provided at the first well 41 of the first conductivity type and may be electrically coupled to the first terminal T1. The cathode region 2C of the first conductivity type may be provided at the second well 42 of the second conductivity type and may be electrically coupled to the second terminal T2. The first gate region 21 of the first conductivity type may be provided at the first well 41 and electrically coupled to the first terminal T1 via the first resistor R1 having one end coupled to the first terminal T1. The second gate region 22 of the second conductivity type may be provided at the second well 42 and electrically coupled to the second terminal T2 via the second resistor R2. The trigger transistor TT may be provided between the second terminal T2 and the other end of the first resistor R1 in the thyristor circuit 20. As described above, since the thyristor circuit 20 of the embodiment includes the first gate region 21, the second gate region 22, the anode region 2A, and the cathode region 2C, functions of the thyristor TH can be implemented. Since the trigger transistor TT is provided between the other end of the first resistor R1 and the second terminal T2, when the trigger transistor TT is on, a current can flow through the first gate. Accordingly, the transistor (transistor Q1) related to the first gate is on, and the transistor (transistor Q2) related to the second gate can be turned on. Accordingly, the thyristor TH can be turned on.

FIG. 7 illustrates an example of an element that can be adopted as the hold element of the embodiment. An element indicated by D10 is an SGPMOS in which a node indicated by D11 is a high-potential-side node and a node indicated by D12 is a low-potential-side node, and is similar to the first hold element 31, the second hold element 32, and the third hold element 33 in FIG. 1. An element indicated by D20 is a PNP bipolar transistor in which a node indicated by D21 is a high-potential-side node and a node indicated by D22 is a low-potential-side node. An element indicated by D30 is a grounded gate N-channel metal-oxide-semiconductor field-effect transistor (GGNMOS) in which a node indicated by D31 is a high-potential-side node and a node indicated by D32 is a low-potential-side node. An element indicated by D40 is an NPN bipolar transistor in which a node indicated by D41 is a high-potential-side node and a node indicated by D42 is a low-potential-side node. An element indicated by D50 is a forward diode in which a node indicated by D51 is a high-potential-side node and a node indicated by D52 is a low-potential-side node. An element indicated by D60 is a reverse diode in which a node indicated by D61 is a high-potential-side node and a node indicated by D62 is a low-potential-side node.

The elements indicated by D10, D20, D30, D40, D50, and D60 may coexist in the voltage hold circuit 30. When hold voltages of the elements indicated by D10, D20, D30, D40, D50, and D60 are different, any hold voltage can be set by appropriately combining these elements.

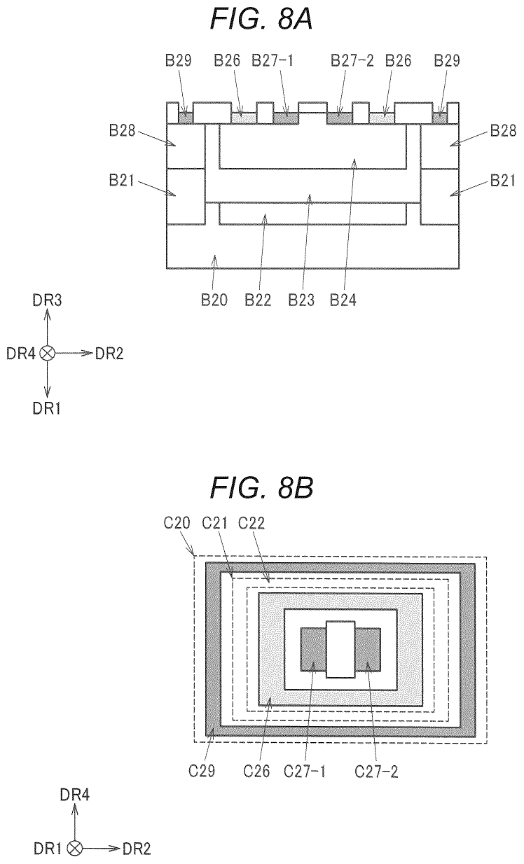

The technique described above with reference to FIGS. 5A, 5B, 6A and 6B may be applied to the elements indicated by D10, D20, D30, D40, D50, and D60. FIG. 8A is a schematic cross-sectional view of the PMOS in the case where the technique of the embodiment is applied, and FIG. 8B is a schematic plan view of the PMOS in the case where the technique of the embodiment is applied. B20 in FIG. 8A is a base substrate, and corresponds to a region indicated by a dotted frame of C20 in FIG. 8B. In FIG. 8A, a P-type well indicated by B21 and an N-type well indicated by B22 are formed at the base substrate indicated by B20. In FIG. 8B, a ring-shaped region between the dotted frame of C20 and a dotted frame of C21 corresponds to a region of the P-type well indicated by B21 in FIG. 8A. In FIG. 8B, a region of a dotted frame of C22 corresponds to a region of the N-type well indicated by B22 in FIG. 8A. An N-type well indicated by B23 in FIG. 8A is formed and a P-type well indicated by B28 is also formed. In FIG. 8B, a region of the dotted frame of C21 corresponds to a region of the N-type well indicated by B23 in FIG. 8A. In FIG. 8B, the ring-shaped region between the dotted frame of C20 and the dotted frame of C21 corresponds to a region of the P-type well indicated by B28 in FIG. 8A. In FIG. 8A, an N-type well indicated by B24 is provided at the N-type well indicated by B23. In FIG. 8B, the region of the dotted frame of C22 corresponds to a region of the N-type well indicated by B24 in FIG. 8A.

After the N-type well indicated by B24 and the P-type well indicated by B28 are formed and planarized, a layer having a pattern of an N-type impurity diffusion region and a layer having a pattern of a P-type impurity diffusion region are formed. The pattern of the N-type impurity diffusion region includes a pattern of a region indicated by B26 in FIG. 8A. The pattern of the P-type impurity diffusion region includes a pattern of a region indicated by B27-1 in FIG. 8A, a pattern of a region indicated by B27-2, and a pattern of a region indicated by B29.

The N-type impurity diffusion region indicated by B26 in FIG. 8A is formed in a ring shape surrounding a region indicated by C27-1 and a region indicated by C27-2, as indicated by C26 in the plan view of FIG. 8B. The P-type impurity diffusion region indicated by B27-1 in FIG. 8A corresponds to the region indicated by C27-1 in the plan view of FIG. 8B, and the P-type impurity diffusion region indicated by B27-2 in FIG. 8A corresponds to the region indicated by C27-2 in the plan view of FIG. 8B. The P-type impurity diffusion region indicated by B29 in FIG. 8A corresponds to a ring-shaped region indicated by C29 in the plan view of FIG. 8B.

In FIG. 8A, the N-type impurity diffusion region indicated by B26 is coupled to a node of the substrate, the P-type impurity diffusion region indicated by B27-1 is coupled to a node of a source, and the P-type impurity diffusion region indicated by B27-2 is coupled to a node of a drain, whereby functions of a PMOS are implemented.

Comparing FIGS. 8A and 8B with FIGS. 6A and 6B, the regions indicated by B20, B21, B22, B23, B24, and B28 in FIG. 8A are common to the regions indicated by B10, B11, B12, B13, B14, and B18 in FIG. 6A. A pattern formation process for the N-type impurity diffusion region indicated by B26 in FIG. 8A is common to the pattern formation process and the manufacturing process for the N-type impurity diffusion region indicated by B16-1 in FIG. 6A. Similarly, a pattern formation process for the N-type impurity diffusion regions indicated by B27-1, B27-2, and B29 in FIG. 8A is common to the pattern formation process and the manufacturing process for the P-type impurity diffusion regions indicated by B16-2, B17, and B19 in FIG. 6A. That is, the SGPMOS indicated by D10 in FIG. 7 can be manufactured by a process common to the P-type DMOS in FIG. 6.

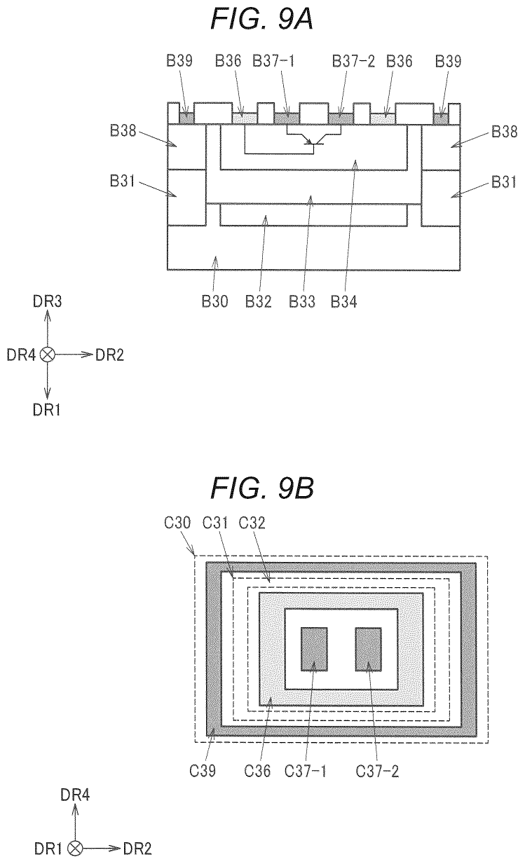

FIG. 9A is a schematic cross-sectional view of the PNP bipolar transistor in the case where the technique of the embodiment is applied, and FIG. 9B is a schematic plan view of the PNP bipolar transistor in the case where the technique of the embodiment is applied. B30 in FIG. 9A indicates a base substrate, and corresponds to a region indicated by a dotted frame of C30 in FIG. 9B. In FIG. 9A, a P-type well indicated by B31 and an N-type well indicated by B32 are formed at the base substrate indicated by B30. In FIG. 9B, a ring-shaped region between the dotted frame of C30 and a dotted frame of C31 corresponds to a region of the P-type well indicated by B31 in FIG. 9A. In FIG. 9B, a region of a dotted frame of C32 corresponds to a region of the N-type well indicated by B32 in FIG. 9A. An N-type well indicated by B33 in FIG. 9A is formed and a P-type well indicated by B38 is also formed. In FIG. 9B, a region of the dotted frame of C31 corresponds to a region of the N-type well indicated by B33 in FIG. 9A. In FIG. 9B, the ring-shaped region between the dotted frame of C30 and the dotted frame of C31 corresponds to a region of the P-type well indicated by B38 in FIG. 9A. In FIG. 9A, an N-type well indicated by B34 is provided at the N-type well indicated by B33. In FIG. 9B, the region of the dotted frame of C32 corresponds to a region of the N-type well indicated by B34 in FIG. 9A.

After the N-type well indicated by B34 and the P-type well indicated by B38 are formed and planarized, a layer having a pattern of an N-type impurity diffusion region and a layer having a pattern of a P-type impurity diffusion region are formed. The pattern of the N-type impurity diffusion region includes a pattern of a region indicated by B36 in FIG. 9A. The pattern of the P-type impurity diffusion region includes a pattern of a region indicated by B37-1 in FIG. 9A, a pattern of a region indicated by B37-2, and a pattern of a region indicated by B39.

The N-type impurity diffusion region indicated by B36 in FIG. 9A is formed in a ring shape surrounding a region indicated by C37-1 and a region indicated by C37-2, as indicated by C36 in the plan view of FIG. 9B. The P-type impurity diffusion region indicated by B37-1 in FIG. 9A corresponds to the region indicated by C37-1 in the plan view of FIG. 9B, and the P-type impurity diffusion region indicated by B37-2 in FIG. 9A corresponds to the region indicated by C37-2 in the plan view of FIG. 9B. The P-type impurity diffusion region indicated by B39 in FIG. 9A corresponds to a ring-shaped region indicated by C39 in the plan view of FIG. 9B.

In FIG. 9A, the N-type impurity diffusion region indicated by B36 is coupled to a node of a base, the P-type impurity diffusion region indicated by B37-1 is coupled to a node of an emitter, and the P-type impurity diffusion region indicated by B37-2 is coupled to a node of a collector, whereby functions of a PNP bipolar transistor are implemented.

Comparing FIGS. 9A and 9B with FIGS. 6A and 6B, the regions indicated by B30, B31, B32, B33, B34, and B38 in FIG. 9A are common to the regions indicated by B10, B11, B12, B13, B14, and B18 in FIG. 6A. A pattern formation process for the N-type impurity diffusion region indicated by B36 in FIG. 9A is common to the pattern formation process and the manufacturing process for the N-type impurity diffusion region indicated by B16-1 in FIG. 6A. Similarly, a pattern formation process for the N-type impurity diffusion regions indicated by B37-1, B37-2, and B39 in FIG. 9A is common to the pattern formation process and the manufacturing process for the P-type impurity diffusion regions indicated by B16-2, B17, and B19 in FIG. 6A. That is, the SGPMOS indicated by D20 in FIG. 7 can be manufactured by a process common to the P-type DMOS in FIG. 6.

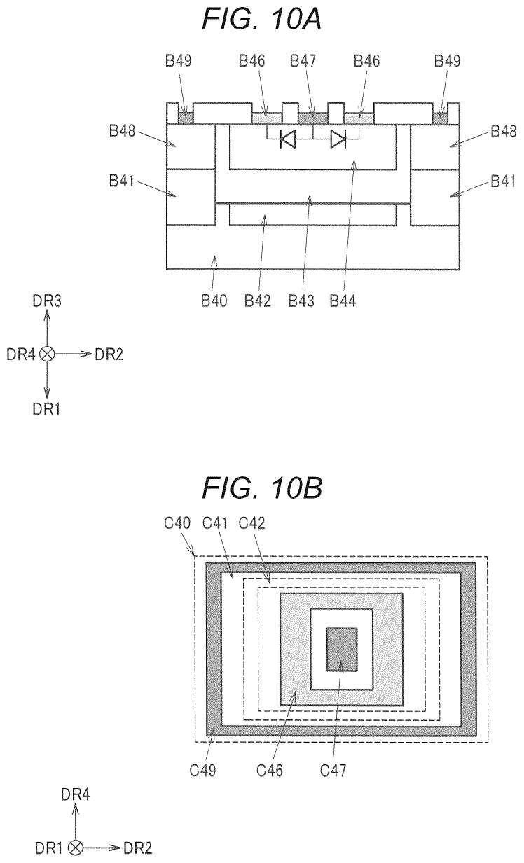

FIG. 10A is a schematic cross-sectional view of a diode in the case where the technique of the embodiment is applied, and FIG. 10B is a schematic plan view of the diode in the case where the technique of the embodiment is applied. B40 in FIG. 10A is a base substrate, and corresponds to a region indicated by a dotted frame of C40 in FIG. 10B. In FIG. 10A, a P-type well indicated by B41 and an N-type well indicated by B42 are formed at the base substrate indicated by B40. In FIG. 10B, a ring-shaped region between the dotted frame of C40 and a dotted frame of C41 corresponds to a region of the P-type well indicated by B41 in FIG. 10A. In FIG. 10B, a region of a dotted frame of C42 corresponds to a region of the N-type well indicated by B42 in FIG. 10A. An N-type well indicated by B43 in FIG. 10A is formed and a P-type well indicated by B48 is also formed. In FIG. 10B, a region of the dotted frame of C41 corresponds to a region of the N-type well indicated by B43 in FIG. 10A. In FIG. 10B, the ring-shaped region between the dotted frame of C40 and the dotted frame of C41 corresponds to a region of the P-type well indicated by B48 in FIG. 10A. In FIG. 10A, an N-type well indicated by B44 is provided at the N-type well indicated by B43. In FIG. 10B, the region of the dotted frame of C42 corresponds to a region of the N-type well indicated by B44 in FIG. 10A.

After the N-type well indicated by B44 and the P-type well indicated by B48 are formed and planarized, a layer having a pattern of an N-type impurity diffusion region and a layer having a pattern of a P-type impurity diffusion region are formed. The pattern of the N-type impurity diffusion region includes a pattern of a region indicated by B46 in FIG. 10A. The pattern of the P-type impurity diffusion region includes a pattern of a region indicated by B47 in FIG. 10A and a pattern of a region indicated by B49.

The N-type impurity diffusion region indicated by B46 in FIG. 10A is formed in a ring shape surrounding a region indicated by C47, as indicated by C46 in the plan view of FIG. 10B. The P-type impurity diffusion region indicated by B47 in FIG. 10A corresponds to the region indicated by C47 in the plan view of FIG. 10B, and the P-type impurity diffusion region indicated by B49 in FIG. 10A corresponds to a ring-shaped region indicated by C49 in the plan view of FIG. 10B.

The N-type impurity diffusion region indicated by B46 in FIG. 10A is coupled to a node of a cathode, and the P-type impurity diffusion region indicated by B47 is coupled to a region of an anode. Accordingly, functions of a diode are implemented.

Comparing FIGS. 10A and 10B with FIGS. 6A and 6B, the regions indicated by B40, B41, B42, B43, B44, and B48 in FIG. 10A are common to the regions indicated by B10, B11, B12, B13, B14, and B18 in FIG. 6A. A pattern formation process for the N-type impurity diffusion region indicated by B46 in FIG. 10A is common to the pattern formation process and the manufacturing process for the N-type impurity diffusion region indicated by B16-1 in FIG. 6A. Similarly, a pattern formation process for the N-type impurity diffusion region indicated by B47 in FIG. 10A is common to the pattern formation process and the manufacturing process for the P-type impurity diffusion regions indicated by B16-2, B17, and B19 in FIG. 6A. That is, the diodes indicated by D50 and D60 in FIG. 7 can be manufactured by the process common to the P-type DMOS in FIGS. 6A and 6B. Similarly, the diode indicated by A0 in FIG. 1 can be manufactured by a process common to the P-type DMOS in FIGS. 6A and 6B.

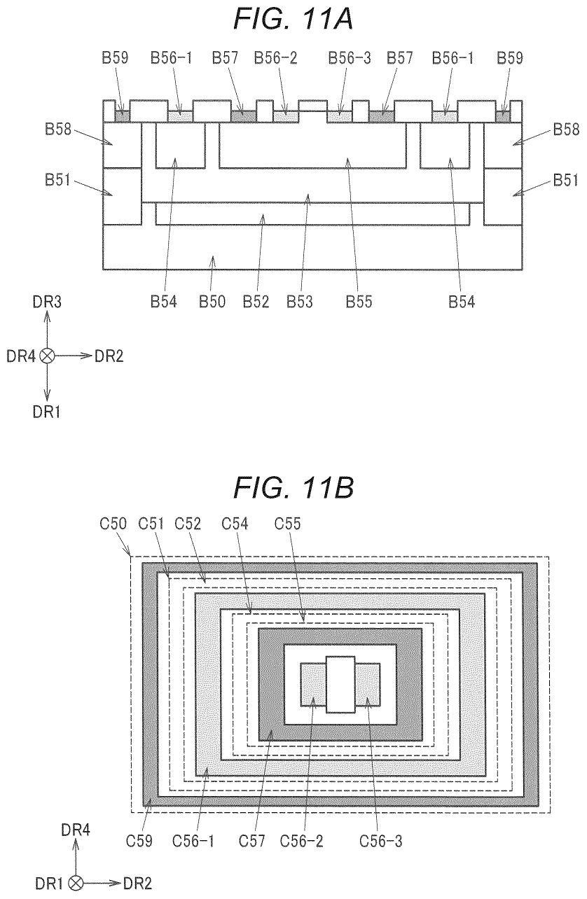

FIG. 11A is a schematic cross-sectional view of an NMOS in the case where the technique of the embodiment is applied, and FIG. 11B is a schematic plan view of the NMOS in the case where the technique of the embodiment is applied. B50 in FIG. 11A is a base substrate, and corresponds to a region indicated by a dotted frame of C50 in FIG. 11B. In FIG. 11A, a P-type well indicated by B51 and an N-type well indicated by B52 are formed at the base substrate indicated by B50. In FIG. 11B, a ring-shaped region between the dotted frame of C50 and a dotted frame of C51 corresponds to a region of the P-type well indicated by B51 in FIG. 11A. In FIG. 11B, a region of a dotted frame of C52 corresponds to a region of the N-type well indicated by B52 in FIG. 11A. An N-type well indicated by B53 in FIG. 11A is formed and a P-type well indicated by B58 is also formed. In FIG. 11B, a region of the dotted frame of C51 corresponds to a region of the N-type well indicated by B53 in FIG. 11A. In FIG. 11B, the ring-shaped region between the dotted frame of C50 and the dotted frame of C51 corresponds to a region of the P-type well indicated by B58 in FIG. 11A. In FIG. 11A, an N-type well indicated by B54 and a P-type well indicated by B55 are provided at the N-type well indicated by B53. In FIG. 11B, a ring-shaped region between the dotted frame of C52 and a dotted frame of C54 corresponds to a region of the N-type well indicated by B54 in FIG. 11A. In FIG. 11B, a region of a dotted frame of C55 corresponds to a region of the P-type well indicated by B55 in FIG. 11A.

After the N-type well indicated by B54, the P-type well indicated by B55, and the P-type well indicated by B58 in FIG. 11A are formed and planarized, a layer having a pattern of an N-type impurity diffusion region and a layer having a pattern of a P-type impurity diffusion region are formed. The pattern of the N-type impurity diffusion region includes a pattern of a region indicated by B56-1 in FIG. 11A, a pattern of a region indicated by B56-2, and a pattern of a region indicated by B56-3. The pattern of the P-type impurity diffusion region includes a pattern of a region indicated by B57 in FIG. 11A and a pattern of a region indicated by B59.

The N-type impurity diffusion region indicated by B56-1 in FIG. 11A is formed in a ring shape surrounding a region indicated by C56-2, a region indicated by C56-3, and a region indicated by C57, as indicated by C56-1 in the plan view of FIG. 11B. The P-type impurity diffusion region indicated by B57 in FIG. 11A is formed in a ring shape surrounding the region indicated by C56-2 and the region indicated by C56-3, as indicated by C57 in the plan view of FIG. 11B. The P-type impurity diffusion region indicated by B59 in FIG. 11A corresponds to a ring-shaped region indicated by C59 in the plan view of FIG. 11B.

In FIG. 11A, the P-type impurity diffusion region indicated by B57 is coupled to a node of the substrate, the N-type impurity diffusion region indicated by B56-2 is coupled to a node of a source, and the N-type impurity diffusion region indicated by B56-3 is coupled to a node of a drain, whereby functions of an NMOS are implemented.

Comparing FIGS. 11A and 11B with FIGS. 6A and 6B, the regions indicated by B50, B51, B52, B53, B54, B55, and B58 in FIG. 11A are common to the regions indicated by B10, B11, B12, B13, B14, B15, and B18 in FIG. 6A. A pattern formation process for the N-type impurity diffusion regions indicated by B56-1, B56-2, and B56-3 in FIG. 11A is common to the pattern formation process and the manufacturing process for the N-type impurity diffusion region indicated by B16-1 in FIG. 6A. Similarly, a pattern formation process for the N-type impurity diffusion regions indicated by B57 and B59 in FIG. 11A is common to the pattern formation process and the manufacturing process for the P-type impurity diffusion regions indicated by B16-2, B17, and B19 in FIG. 6A. That is, the NMOS indicated by D30 in FIG. 7 can be manufactured by a process common to the P-type DMOS in FIG. 6.

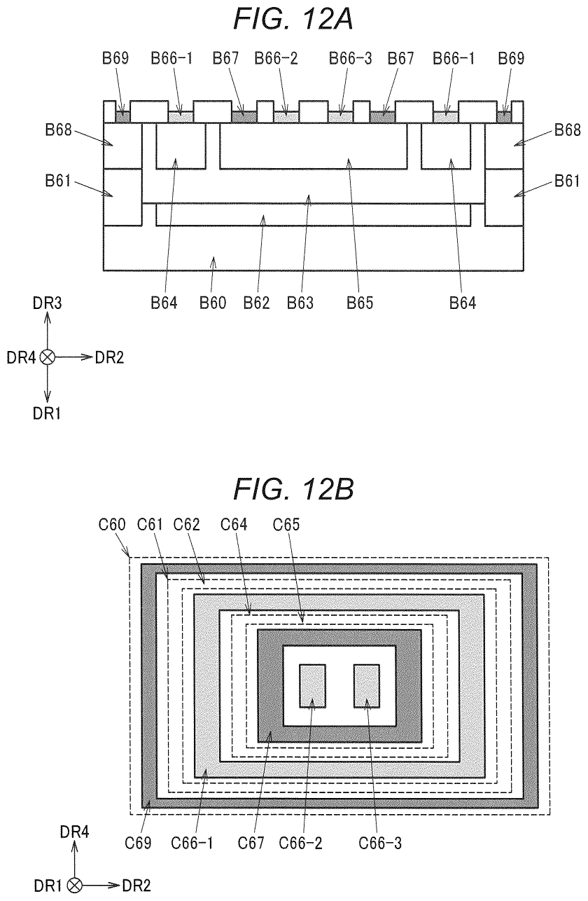

FIG. 12A is a schematic cross-sectional view of an NPN bipolar transistor in the case where the technique of the embodiment is applied, and FIG. 12B is a schematic plan view of the NPN bipolar transistor in the case where the technique of the embodiment is applied. B60 in FIG. 12A is a base substrate, and corresponds to a region indicated by a dotted frame of C60 in FIG. 12B. In FIG. 12A, a P-type well indicated by B61 and an N-type well indicated by B62 are formed at the base substrate indicated by B60. In FIG. 12B, a ring-shaped region between the dotted frame of C60 and a dotted frame of C61 corresponds to a region of the P-type well indicated by B61 in FIG. 12A. In FIG. 12B, a region of a dotted frame of C62 corresponds to a region of the N-type well indicated by B62 in FIG. 12A. An N-type well indicated by B63 in FIG. 12A is formed and a P-type well indicated by B68 is also formed. In FIG. 12B, a region of the dotted frame of C61 corresponds to a region of the N-type well indicated by B63 in FIG. 12A. In FIG. 12B, the ring-shaped region between the dotted frame of C60 and the dotted frame of C61 corresponds to a region of the P-type well indicated by B68 in FIG. 12A. In FIG. 12A, an N-type well indicated by B64 and a P-type well indicated by B65 are provided at the N-type well indicated by B63. In FIG. 12B, a ring-shaped region between the dotted frame of C62 and a dotted frame of C64 corresponds to a region of the N-type well indicated by B64 in FIG. 12A. In FIG. 12B, a region of a dotted frame of C65 corresponds to a region of the P-type well indicated by B65 in FIG. 12A.

After the N-type well indicated by B64, the P-type well indicated by B65, and the P-type well indicated by B68 in FIG. 12A are formed and planarized, a layer having a pattern of an N-type impurity diffusion region and a layer having a pattern of a P-type impurity diffusion region are formed. The pattern of the N-type impurity diffusion region includes a pattern of a region indicated by B66-1 in FIG. 12A, a pattern of a region indicated by B66-2, and a pattern of a region indicated by B66-3. The pattern of the P-type impurity diffusion region includes a pattern of a region indicated by B67 in FIG. 12A and a pattern of a region indicated by B69.

The N-type impurity diffusion region indicated by B66-1 in FIG. 12A is formed in a ring shape surrounding a region indicated by C66-2, a region indicated by C66-3, and a region indicated by C67, as indicated by C66-1 in the plan view of FIG. 12B. The P-type impurity diffusion region indicated by B67 in FIG. 12A is formed in a ring shape surrounding the region indicated by C66-2 and the region indicated by C66-3, as indicated by C67 in the plan view of FIG. 12B. The P-type impurity diffusion region indicated by B69 in FIG. 12A corresponds to a ring-shaped region indicated by C69 in the plan view of FIG. 12B.

In FIG. 12A, the P-type impurity diffusion region indicated by B67 is coupled to a node of the substrate, the N-type impurity diffusion region indicated by B66-2 is coupled to a node of a source, and the N-type impurity diffusion region indicated by B66-3 is coupled to a node of a drain, whereby functions of an NPN bipolar transistor are implemented.

Comparing FIGS. 12A and 12B with FIGS. 6A and 6B, the regions indicated by B60, B61, B62, B63, B64, B65, and B68 in FIG. 12A are common to the regions indicated by B10, B11, B12, B13, B14, B15, and B18 in FIG. 6A. A pattern formation process for the N-type impurity diffusion regions indicated by B66-1, B66-2, and B66-3 in FIG. 12A is common to the pattern formation process and the manufacturing process for the N-type impurity diffusion region indicated by B16-1 in FIG. 6A. Similarly, a pattern formation process for the N-type impurity diffusion regions indicated by B67 and B69 in FIG. 12A is common to the pattern formation process and the manufacturing process for the P-type impurity diffusion regions indicated by B16-2, B17, and B19 in FIG. 6A. That is, the NPN bipolar transistor indicated by D40 in FIG. 7 can be manufactured by a process common to the P-type DMOS in FIG. 6.

Similarly, the predetermined capacitor CS in FIG. 1 can also have a common manufacturing process. FIG. 13A is a schematic cross-sectional view of the predetermined capacitor CS of the embodiment, FIG. 13B is a plan view taken along a line E2-E2 in FIG. 13A, and FIG. 13C is a plan view taken along a line E3-E3 in FIG. 13A. A layer indicated by E1 in FIG. 13A is a layer schematically illustrating a wiring layer formed by the back-end process, and an insulating layer or the like is appropriately omitted for convenience of description. The insulating layer is formed of an oxide film of silicon oxide or the like. Regions B80, B81, B82, B83, B84, B85, B86, B87, B88, and B89 in FIG. 13A are pattern regions of the wiring layer. In the embodiment, the wiring layer related to wiring regions indicated by B80, B81, B82, B83, and B84 is referred to as a first metal layer, and the wiring layer related to wiring regions indicated by B85, B86, B87, B88, and B89 is referred to as a second metal layer.

In FIG. 13A, a layer indicated by B70 is a layer of a base substrate, a layer indicated by B71 is a layer including a P-well region similar to B11 in FIG. 6A, and a layer indicated by B78 is a layer including a P-well region similar to B18 in FIG. 6A. That is, the front-end process for manufacturing the predetermined capacitor CS in FIG. 1 includes, of the front-end process for the P-type DMOS in FIG. 6, forming the P-well region of B11 and forming the P-well region of B18. Accordingly, the front-end process for the predetermined capacitor CS can be made common to the front-end process for the P-type DMOS.

The wiring layer patterned in a comb tooth shape as indicated by C80, C81, C82, C83, and C84 in the plan view of FIG. 13B and the wiring layer patterned in a comb tooth shape as indicated by C85, C86, C87, C88, and C89 in the plan view of FIG. 13C face each other, constituting the capacitor. Wirings indicated by C80, C81, C82, C83, and C84 in FIG. 13B correspond to wirings indicated by B80, B81, B82, B83, and B84 in the cross-sectional view of FIG. 13A, respectively. Similarly, wirings indicated by C85, C86, C87, C88, and C89 in FIG. 13C correspond to wirings B85, B86, B87, B88, and B89 in the cross-sectional view of FIG. 13A, respectively. In the embodiment, the wiring layer illustrated in FIG. 13B is referred to as a first electrode, and the wiring layer illustrated in FIG. 13C is referred to as a second electrode.

As described above, the predetermined capacitor CS of the embodiment constitutes a metal oxide metal (MOM) capacitor. As described above, in the circuit device 10 of the embodiment, the predetermined capacitor CS is a MOM capacitor. In this way, the manufacturing process for the predetermined capacitor CS and the manufacturing process for the other transistors can be made common. In the circuit device 10 of the embodiment, the MOM capacitor includes the first electrode and the second electrode. The first electrode is provided at the first metal layer and has a comb tooth shape in a plan view, and the second electrode is provided at the second metal layer, faces the first electrode and has a comb tooth shape in a plan view. In this way, it is possible to increase the electrostatic capacitance of the predetermined capacitor CS while preventing an increase in chip area: related to the predetermined capacitor CS.

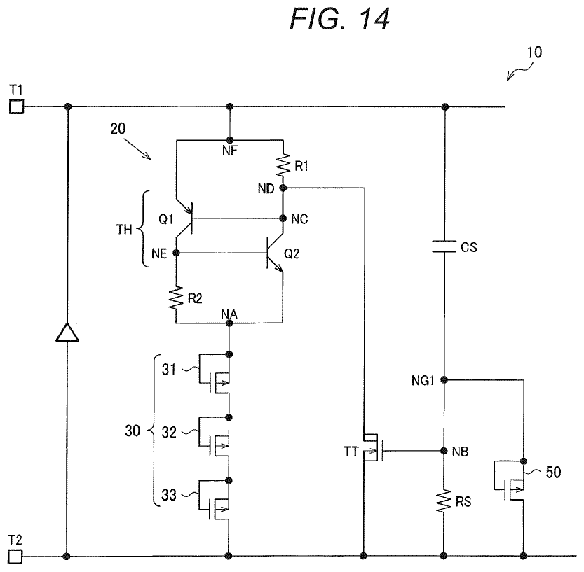

The circuit device 10 of the embodiment may be implemented as a configuration example illustrated in FIG. 14. The configuration example in FIG. 14 is different from the configuration example in FIG. 1 in further including a gate protection circuit 50 that protects the gate of the trigger transistor TT. Specifically, for example, in FIG. 14, the gate protection circuit 50 is disposed between a node NG1 and the second terminal T2. In other words, the gate protection circuit 50 is provided between the gate of the trigger transistor TT and the second terminal T2. In a case where the trigger transistor TT is the above-described DMOS, the breakdown voltage between the gate and the source of the DMOS is lower than the breakdown voltage between the source and the drain. Therefore, in a case where the potential at the node NB increases abruptly when the ESD surge is applied to the first terminal T1, the gate of the trigger transistor TT may be damaged. In this regard, by applying the technique of the embodiment, the gate of the trigger transistor TT can be protected from an overvoltage, and the circuit device 10 can appropriately function.

Although the SGPMOS is exemplified as an element constituting the gate protection circuit 50 in FIG. 14, the PNP bipolar transistor indicated by D20 in FIG. 7, the GGNMOS indicated by D30, the NPN bipolar transistor indicated by D40, the reverse diode indicated by D50, or the like may be used. Specifically, the element may be appropriately determined based on a voltage to be clamped or the like, in consideration of the breakdown voltage between the gate and the source of the trigger transistor TT. As described above, the circuit device 10 of the embodiment includes the gate protection circuit 50 provided between the gate of the trigger transistor TT and the second terminal T2. In this way, in addition to the above effects, the gate and source of the trigger transistor TT can be protected from an overvoltage.

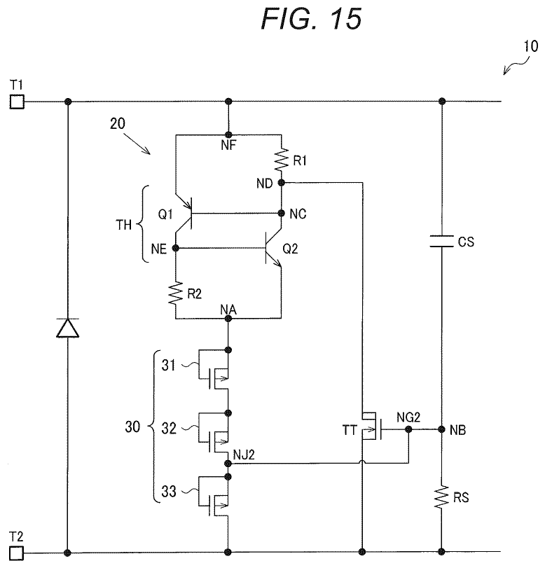

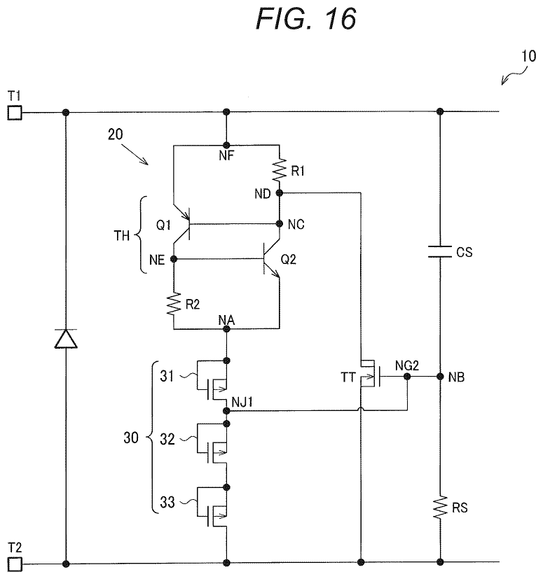

For example, the circuit device 10 of the embodiment may be implemented as configuration examples illustrated in FIGS. 15 and 16, so that the gate of the trigger transistor TT is protected from an overvoltage by using the hold element of the voltage hold circuit 30. In this case, the gate of the trigger transistor TT may be coupled to a coupling node between an n-th hold element and an (n+1)-th hold element. Specifically, for example, in the case of the configuration in FIG. 15, since a node NG2 coupled to the gate of the trigger transistor TT is coupled to a node NJ2, which is a coupling node between the second hold element 32 and the third hold element 33, n=2. When the third hold element 33 is the above-described SGPMOS, since the breakdown voltage is 8 V, the gate of the trigger transistor TT is clamped and protected at a voltage of 8 V. For example, in the case of the configuration in FIG. 16, since the node NG2 is coupled to a node NJ1 that is a coupling node between the first hold element 31 and the second hold element 32, n=1. When the second hold element 32 and the third hold element 33 are the above-described SGPMOS, the gate of the trigger transistor TT is clamped and protected at a voltage of 16 V. As described above, since the gate of the trigger transistor TT is coupled to the coupling node between the n-th hold element and the (n +1)-th hold element, and the hold element such as the (n+1)-th hold element is appropriately determined, the gate and the source of the trigger transistor can be clamped and protected at a desired voltage.

As described above, in the circuit device 10 of the embodiment, the voltage hold circuit 30 includes a plurality of hold elements coupled in series, and the coupling node between the n-th hold element and the (n+1)-th hold element among the plurality of hold elements is coupled to the gate of the trigger transistor TT. In this way, the gate and the source of the trigger transistor TT are protected from an overvoltage, and it is possible to prevent an increase in chip area related to the circuit device 10. In the configuration example in FIG. 14, the gate protection circuit 50 is required, but in the configuration examples in FIGS. 15 and 16, the gate and source of the trigger transistor TT can be protected from an overvoltage without using the gate protection circuit 50.

For example, in the circuit device 10 of the embodiment, the trigger transistor TT may be implemented by a P-type DMOS. Specifically, the circuit device 10 of the embodiment may be implemented as a configuration example illustrated in FIG. 17. In FIG. 17, the voltage hold circuit 30 includes a plurality of hold elements coupled directly as in FIG. 1, and is provided between the first terminal T1 and the node NF. The thyristor circuit 20 is provided between the node NF and the node NA. The node NA is coupled to the second terminal T2. That is, the thyristor circuit 20 and the voltage hold circuit 30 are directly coupled between the first terminal T1 and the second terminal T2 in the configuration in FIG. 17, which is similar to that in FIG. 1. In the circuit device 10 illustrated in FIG. 17, the node NF functions as the first node.

Further, the trigger transistor TT, the predetermined capacitor CS, and the predetermined resistor RS constitute the trigger circuit in the configuration in FIG. 17, which is similar to that in FIG. 1. In FIG. 17, the predetermined resistor RS has one end coupled to the first terminal T1 and the other end coupled to the node NB. The source of the trigger transistor TT is coupled to the first terminal T1, the drain of the trigger transistor TT is coupled to the node NL that is a node on one end side of the second resistor R2 of the thyristor circuit 20, and the gate of the trigger transistor TT is coupled to the node NB. The predetermined capacitor CS is provided between the node NB and the second terminal T2.

When the circuit device 10 in FIG. 17 is normally operated, that is, when the potential of the second terminal T2 is 0 V as the ground voltage, and a voltage of 24 V is applied to the first terminal T1, a voltage of 24 V is generated between the source and the gate of the trigger transistor TT. Since the trigger transistor TT is a P-type DMOS as described above, the trigger transistor TT is not damaged. After the predetermined capacitor CS is charged, the predetermined resistor RS functions as a pull-up resistor, and thus the potential of the node NB is maintained at 24 V of the first terminal T1. That is, since there is no potential difference between the gate and the source of the trigger transistor TT, the trigger transistor TT is off.

FIG. 18 is a diagram illustrating an operation of the circuit device 10 when an ESD surge is applied. For example, it is assumed that a surge voltage of 40 V is applied to the first terminal T1. At this time, the potential of a gate is maintained at a voltage, which is a voltage immediately before application of the ESD surge, due to capacitive coupling. More specifically, although the voltage between the source and the drain of the trigger transistor TT is 40 V, a time constant of the RC circuit is set sufficiently large, and the potential of the node NB is maintained as a low level until the time corresponding to the time constant elapses. Accordingly, the trigger transistor TT is on, and a current flows as indicated by an arrow A11. More accurately, the arrow A11 is directed in the order of the first terminal T1, the source of the trigger transistor TT, the drain of the trigger transistor TT, the node NL, the second resistor R2, the node NA, and the second terminal T2. Accordingly, since the current flows through the second resistor R2, the potential of the node NE, which is a node of the base of the transistor Q2, is higher than that of the node NA, so that a current flows as indicated by an arrow A12. More accurately, the arrow indicated by A12 is directed in the order of the first terminal T1, the source of the trigger transistor TT, the drain of the trigger transistor TT, the node NL, the node NE, the base of the transistor Q2, the emitter of the transistor Q2, the node NA, and the second terminal T2. Accordingly, the transistor Q2 is on, and a current flows as indicated by an arrow A13. More accurately, the arrow A13 is directed in the order of the first terminal T1, the voltage hold circuit 30, the node NF, the first resistor R1, the node NC, the collector of the transistor Q2, the emitter of the transistor Q2, the node NA, and the second terminal T2. Accordingly, a current flows through the first resistor R1, and the potential of the node NC, which is a node of the base of the transistor Q1, is lower than that of the node NF. Accordingly, a current flows as indicated by an arrow A14. More accurately, the arrow indicated by A14 is directed in the order of the first terminal T1, the voltage hold circuit 30, the node NF, the emitter of the transistor Q1, the base of the transistor Q1, the node NC, the collector of the transistor Q2, the emitter of the transistor Q2, the node NA, and the second terminal T2. Accordingly, a base current of the transistor Q1 flows, and the transistor Q1 is on. Accordingly, a current flows as indicated by an arrow A15. More accurately, the arrow A15 is directed in the order of the first terminal T1, the voltage hold circuit 30, the node NF, the emitter of the transistor Q1, the collector of the transistor Q1, the node NE, the base of the transistor Q2, the emitter of the transistor Q2, the node NA, and the second terminal T2. That is, the thyristor TH is on.

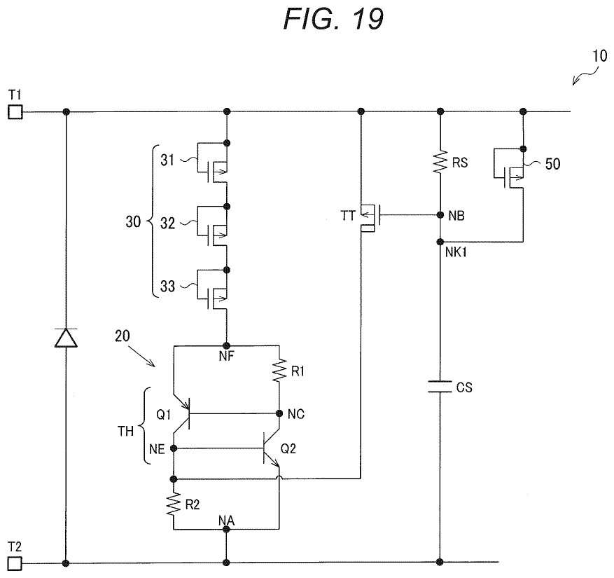

The technique described above with reference to FIG. 14 may be combined in the circuit device 10 in FIG. 17. That is, the circuit device 10 of the embodiment may be implemented as a configuration example illustrated in FIG. 19. In FIG. 19, the gate protection circuit 50 is provided between the first terminal T1 and a node NK1. The node NK1 is a node between the predetermined resistor RS and the predetermined capacitor CS. Accordingly, the gate of the trigger transistor TT is protected by the gate protection circuit 50.

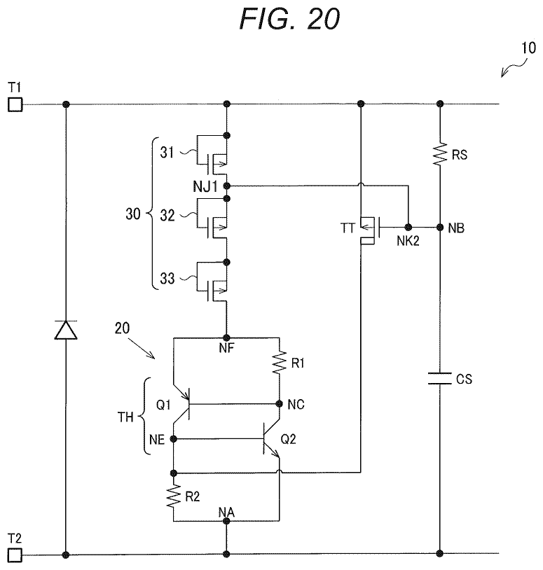

The technique described above with reference to FIG. 15 may be combined in the circuit device 10 in FIG. 17. That is, in the circuit device 10 of the embodiment, the gate of the trigger transistor TT may be coupled to a coupling node between an n-th hold element and an (n+1)-th hold element of the voltage hold circuit 30. Specifically, for example, in FIG. 20, since the gate of the trigger transistor TT is coupled to the node NJ1 that is a coupling node between the first hold element 31 and the second hold element 32, n=1.

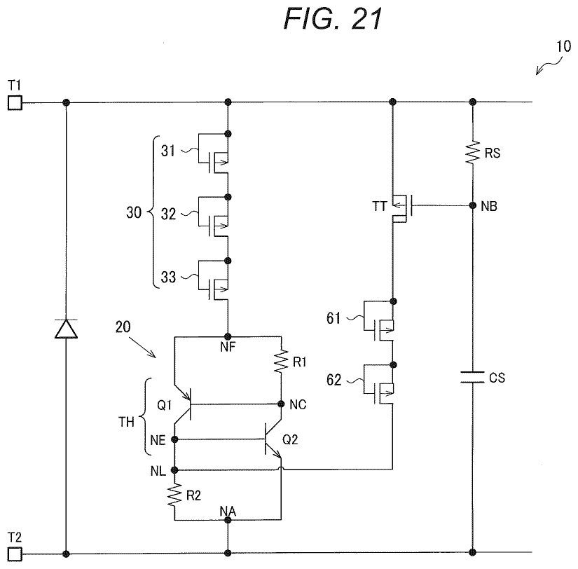

The circuit device 10 of the embodiment may be implemented as a configuration example illustrated in FIG. 21. The configuration example in FIG. 21 is different from the configuration example in FIG. 17 in that a first predetermined element 61 and a second predetermined element 62 as predetermined elements are coupled in series to the drain of the trigger transistor TT that is a P-type DMOS. The number of the predetermined elements is not limited to two, and can be appropriately determined. Although the SGPMOS is exemplified as the predetermined element in FIG. 21, other elements may be adopted in consideration of a value of a breakdown voltage.

By adopting the circuit device 10 as illustrated in FIG. 21, the breakdown voltage of the trigger transistor TT can be reduced as compared with the circuit device 10 in FIG. 17. Specifically, for example, when the absolute maximum rated voltage between the first terminal T1 and the second terminal T2 is 40 V as described above, it is sufficient that a sum of absolute maximum rated voltages of the trigger transistor TT, the first predetermined element 61, and the second predetermined element 62 is 40 V. That is, since the absolute maximum rated voltage of the SGPMOS is 7 V as described above, it is sufficient that the absolute maximum rated voltage between the source and the drain of the trigger transistor TT is 26 V. The circuit devices 10 in FIGS. 1, 14, 15, 17, 19, and 20 are configured such that a voltage applied between the source and the drain of the trigger transistor TT is equal to a voltage between the first terminal T1 and the second terminal T2. In other words, the absolute maximum rated voltage between the source and the drain of the trigger transistor TT according to the above-described technique needs to be equal to or higher than the maximum rated voltage (=40 V) between the first terminal T1 and the second terminal T2. In this regard, the trigger transistor TT, of which the absolute maximum rated voltage between the source and the drain is reduced, can be adopted in the circuit device 10 in FIG. 21.

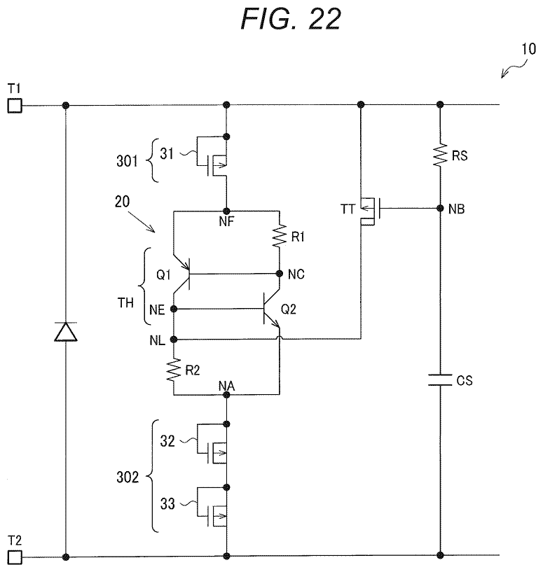

The circuit device 10 of the embodiment may be implemented as a configuration example illustrated in FIG. 22. In FIG. 22, the voltage hold circuit 30 is divided into a first voltage hold circuit 301 and a second voltage hold circuit 302. The first voltage hold circuit 301 corresponds to the voltage hold circuit 30 in FIG. 21, and is provided between the first terminal T1 and the node NF. The second voltage hold circuit 302 is provided between the node NA and the second terminal T2. Similarly to the voltage hold circuit 30 in FIG. 17, the first voltage hold circuit 301 in FIG. 22 has a function of increasing the hold voltage of the circuit device 10. The second voltage hold circuit 302 in FIG. 22 has a function of increasing the hold voltage of the circuit device 10, and also has a function of lowering a lower limit value of the absolute maximum rated voltage between the source and the drain of the trigger transistor TT similarly to the predetermined element in FIG. 21. In FIG. 22, although the first voltage hold circuit 301 includes the first hold element 31 and the second voltage hold circuit 302 includes the second hold element 32 and the third hold element 33, the number of the hold elements is not limited. As described above, the circuit device 10 of the embodiment includes the second voltage hold circuit 302 provided between the second terminal T2 and the thyristor circuit 20. In this way, the trigger transistor TT having a low breakdown voltage between the source and the drain can be used in the circuit device 10.

FIG. 23 is a diagram illustrating an operation occurring when an ESD surge is applied to the circuit device 10 illustrated in FIG. 22. For example, it is assumed that a surge voltage of 40 V is applied to the first terminal T1. At this time, the potential of a gate is maintained at a voltage, which is a voltage immediately before application of the ESD surge, due to capacitive coupling. More specifically, although the voltage between the source and the drain of the trigger transistor TT is 40 V, a time constant of the RC circuit is set sufficiently large, and the potential of the node NB is maintained as a low level until the time corresponding to the time constant elapses. Accordingly, the trigger transistor TT is on, and a current flows as indicated by an arrow A2. More accurately, the arrow A21 is directed in the order of the first terminal T1, the source of the trigger transistor TT, the drain of the trigger transistor TT, the node NL, the second resistor R2, the node NA, the second voltage hold circuit 302, and the second terminal T2. Accordingly, since the current flows through the second resistor R2, the potential of the node NE, which is a node of the base of the transistor Q2, is higher than that of the node NA, so that a current flows as indicated by an arrow A22. More accurately, the arrow indicated by A22 is directed in the order of the first terminal T1, the source of the trigger transistor TT, the drain of the trigger transistor TT, the node NL, the node NE, the base of the transistor Q2, the emitter of the transistor Q2, the node NA, the second voltage hold circuit 302, and the second terminal T2. Accordingly, the transistor Q2 is on, and a current flows as indicated by an arrow A23. More accurately, the arrow A23 is directed in the order of the first terminal T1, the first voltage hold circuit 301, the node NF, the first resistor R1, the node NC, the collector of the transistor Q2, the emitter of the transistor Q2, the node NA, the second voltage hold circuit 302, and the second terminal T2. Accordingly, a current flows through the first resistor R1, and the potential of the node NC, which is a node of the base of the transistor Q1, is lower than that of the node NF. Accordingly, a current flows as indicated by an arrow A24. More accurately, the arrow indicated by A24 is directed in the order of the first terminal T1, the first voltage hold circuit 301, the node NF, the emitter of the transistor Q1, the base of the transistor Q1, the node NC, the collector of the transistor Q2, the emitter of the transistor Q2, the node NA, the second voltage hold circuit 302, and the second terminal T2. Accordingly, a base current of the transistor Q1 flows, and the transistor Q1 is on. Accordingly, a current flows as indicated by an arrow A25. More accurately, the arrow indicated by A25 is directed in the order of the first terminal T1, the first voltage hold circuit 301, the node NF, the emitter of the transistor Q1, the collector of the transistor Q1, the node NE, the base of the transistor Q2, the emitter of the transistor Q2, the node NA, the second voltage hold circuit 302, and the second terminal T2. That is, the thyristor TH is on.

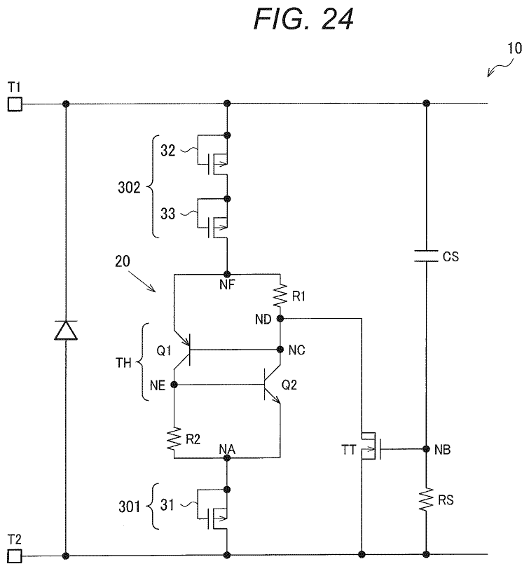

FIG. 22 illustrates an example in which the above-described technique is applied to a case where the trigger transistor TT is a P-type DMOS as in FIG. 17, and the technique may be applied to a case where the trigger transistor TT is an N-type DMOS. That is, the technique described with reference to FIG. 22 may be applied to the configuration example of the circuit device 10 in FIG. 1. Specifically, for example, the circuit device 10 may be implemented as a configuration example in FIG. 24. Comparing FIG. 24 with FIG. 1, the voltage hold circuit 30 is divided into the first voltage hold circuit 301 and the second voltage hold circuit 302. The first voltage hold circuit 301 corresponds to the voltage hold circuit 30 in FIG. 1, and is provided between the node NA and the second terminal T2. The second voltage hold circuit 302 is provided between the first terminal T1 and the node NF. Similarly to the voltage hold circuit 30 in FIG. 1, the first voltage hold circuit 301 in FIG. 24 has a function of increasing the hold voltage of the circuit device 10. The second voltage hold circuit 302 in FIG. 24 has a function of increasing the hold voltage of the circuit device 10, and also has a function of lowering a lower limit value of the absolute maximum rated voltage between the source and the drain of the trigger transistor TT similarly to the predetermined element in FIG. 21. As described above, the circuit device 10 of the embodiment includes the second voltage hold circuit 302 provided between the first terminal T1 and the thyristor circuit 20. In this way, the trigger transistor TT having a low breakdown voltage between the source and the drain can be used in the circuit device 10.

FIG. 25 is a diagram illustrating an operation occurring when an ESD surge is applied to the circuit device 10 illustrated in FIG. 24. It is assumed that the potential of the first terminal T1 increases to, for example, 40 V. At this time, the potential of the node NB increases due to capacitive coupling of the predetermined capacitor CS. That is, the potential of the trigger transistor TT on the gate side increases. Accordingly, since a potential difference occurs between the gate and the source of the trigger transistor TT, the trigger transistor TT is turned on, and a current flows in a direction of an arrow indicated by A31. More accurately, the arrow indicated by A31 is directed in the order of the first terminal T1, the second voltage hold circuit 302, the node NF, the first resistor R1, the node ND, the drain of the trigger transistor TT, the source of the trigger transistor TT, and the second terminal T2. Accordingly, a current flows through the first resistor R1, and the potential of the node ND coupled to the base of the transistor Q1 is lower than the potential of the node NF. Accordingly, a current flows in a direction of an arrow indicated by A32. More accurately, the arrow indicated by A32 is directed in the order of the first terminal T1, the second voltage hold circuit 302, the node NF, the emitter of the transistor Q1, the base of the transistor Q1, the node NC, the node ND, the drain of the trigger transistor TT, the source of the trigger transistor TT, and the second terminal T2. Accordingly, a base current of the transistor Q1 flows, and the transistor Q1 is on.

Accordingly, a current flows in a direction of an arrow indicated by A33. More accurately, the arrow A33 is directed in the order of the first terminal T1, the second voltage hold circuit 302, the node NF, the emitter of the transistor Q1, the collector of the transistor Q1, the node NE, the second resistor R2, the node NA, the first voltage hold circuit 301, and the second terminal T2. Accordingly, a current flows through the second resistor R2, and the potential of the node NE coupled to the base of the transistor Q2 is higher than the potential of the node NA. Accordingly, a current flows in a direction of an arrow indicated by A34. More accurately, the arrow indicated by A34 is directed in the order of the first terminal T1, the second voltage hold circuit 302, the node NF, the emitter of the transistor Q1, the collector of the transistor Q1, the node NE, the emitter of the transistor Q2, the node NA, the first voltage hold circuit 30, 1 and the second terminal T2. Accordingly, a base current of the transistor Q2 flows, and the transistor Q2 is on. Accordingly, a current flows in a direction of an arrow indicated by A35. More accurately, the arrow indicated by A35 is directed in the order of the first terminal T1, the first voltage hold circuit 301, the node NF, the emitter of the transistor Q1, the node NC, the collector of the transistor Q2, the emitter of the transistor Q2, the node NA, the first voltage hold circuit 301, and the second terminal T2. That is, the thyristor TH is on.

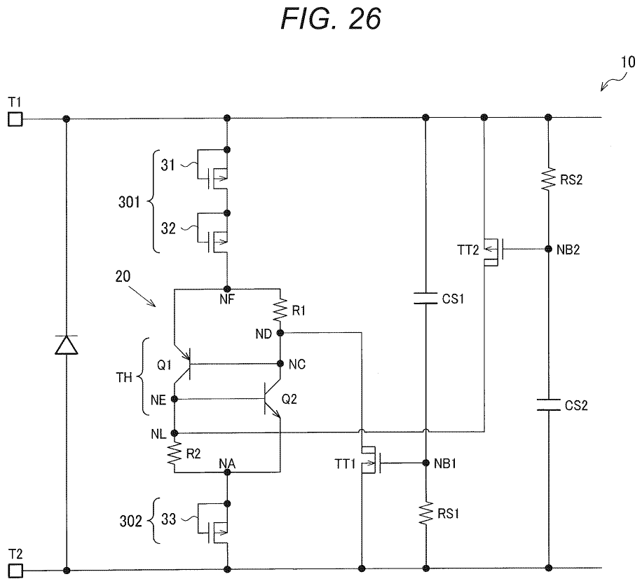

The above is a configuration example in which a trigger current is caused to flow in the thyristor circuit 20 by one trigger circuit. Alternatively, for example, a configuration example may be adopted in which a trigger current is caused to flow in the thyristor circuit 20 by two trigger circuits. Specifically, for example, the circuit device 10 of the embodiment may be implemented as a configuration example in FIG. 26. The circuit device 10 in FIG. 26 is different from the circuit device 10 in FIG. 24 in further including a second trigger circuit. A first trigger circuit includes a first trigger transistor TT1, a first predetermined capacitor CS1, and a first predetermined resistor RS1, and corresponds to the trigger circuit in FIG. 24. The second trigger circuit includes a second trigger transistor TT2, a second predetermined capacitor CS2, and a second predetermined resistor RS2. The second trigger transistor TT2 is, for example, a P-type DMOS, a source thereof is coupled to the first terminal T1, a drain thereof is coupled to the node NL of the thyristor circuit 20, and a gate thereof is coupled to a node NB2. The second predetermined resistor RS2 is provided between the first terminal T1 and the node NB2. The second predetermined capacitor CS2 is provided between the node NB2 and the second terminal T2.

FIG. 27 is a diagram illustrating an operation occurring when an ESD surge is applied to the circuit device 10 illustrated in FIG. 26. It is assumed that the potential of the first terminal T1 increases to, for example, 40 V. At this time, the potential of the node NB1 increases due to capacitive coupling of the first predetermined capacitor CS1. That is, the potential of the first trigger transistor TT1 on the gate side increases. Accordingly, since a potential difference occurs between a gate and a source of the first trigger transistor TT1, the first trigger transistor TT1 is turned on, and a current flows in a direction of an arrow indicated by A41. More accurately, the arrow indicated by A41 is directed in the order of the first terminal T1, the first voltage hold circuit 301, the node NF, the first resistor R1, the node ND, a drain of the trigger transistor TTI, the source of the first trigger transistor TT1, and the second terminal T2. Due to the capacitive coupling of the second predetermined capacitor CS2, the potential of the node NB2 is maintained at a voltage immediately before application of the ESD surge. More specifically, although the voltage between the source and the drain of the second trigger transistor TT2 is 40 V, a time constant of the RC circuit is set sufficiently large, and the potential of the node NB is maintained as a low level until the time corresponding to the time constant elapses. Accordingly, the second trigger transistor TT2 is turned on, and a current flows as indicated by an arrow A51. More accurately, the arrow A51 is directed in the order of the first terminal T1, the source of the second trigger transistor TT2, the drain of the second trigger transistor TT2, the node NL, the second resistor R2, the node NA, the second voltage hold circuit 302, and the second terminal T2.

Accordingly, a current flows through the first resistor R1 and the potential of the node ND coupled to the base of the transistor Q1 is lower than the potential of the node NF, and a current flows through the second resistor R2 and the potential of the node NE coupled to the base of the transistor Q2 is higher than the potential of the node NA. Accordingly, a current flows in a direction of an arrow indicated by A42, and a current flows in a direction of an arrow indicated by A52. More accurately, the arrow indicated by A42 is directed in the order of the first terminal T1, the first voltage hold circuit 301, the node NF, the emitter of the transistor Q1, the base of the transistor Q1, the node NC, the node ND, the drain of the first trigger transistor TT1, the source of the first trigger transistor TTI, and the second terminal T2. More accurately, the arrow indicated by A52 is directed in the order of the first terminal T1, the source of the second trigger transistor TT2, the drain of the second trigger transistor TT2, the node NL, the node NE, the base of the transistor Q2, the emitter of the transistor Q2, the node NA, the second voltage hold circuit 302, and the second terminal T2.

Accordingly, a current flows in a direction of an arrow indicated by A43, and a current flows in a direction of an arrow indicated by A53. More accurately, the arrow indicated by A43 is directed in the order of the first terminal T1, the first voltage hold circuit 301, the node NF, the emitter of the transistor Q1, the collector of the transistor Q1, the node NE, the second resistor R2, the node NA, the second voltage hold circuit 302, and the second terminal T2. More accurately, the arrow indicated by A53 is directed in the order of the first terminal T1, the first voltage hold circuit 301, the node NF, the first resistor R1, the node NC, the collector of the transistor Q2, the emitter of the transistor Q2, the node NA, the second voltage hold circuit 302, and the second terminal T2. That is, the thyristor TH is on.

As described above, in the circuit device 10 in FIG. 26, an operation step from a timing at which the ESD surge current flows to a timing at which the thyristor TH is on includes a step in which the potential of the first terminal T1 or the like increases, a step in which the currents indicated by the arrows A41 and A51 are generated, a step in which the currents indicated by the arrows A42 and A52 are generated, and a step in which the currents indicated by the arrows A43 and A53 are generated. On the other hand, in the case in FIG. 1, the operation step includes a step in which the potential of the first terminal T1 or the like increases, a step in which the current indicated by the arrow A1 is generated, a step in which the current indicated by the arrow A2 is generated, a step in which the current indicated by the arrow A3 is generated, a step in which the current indicated by the arrow A4 is generated, and a step in which the current indicated by the arrow A5 is generated. That is, in the configuration example in FIG. 1, the number of operation steps required until the thyristor TH is on is 6, and in the configuration example in FIG. 26, the number of operation steps required until the thyristor TH is on is 4. In this way, by implementing the circuit device 10 in FIG. 26, it is possible to shorten the time required from the timing at which the ESD surge current flows to the timing at which the thyristor TH is on. Accordingly, it is possible to more reliably protect the internal circuit from static electricity. Whether to implement the circuit device 10 in FIG. 1 or the circuit device 10 in FIG. 26 may be appropriately determined in consideration of the chip size and the like of the semiconductor device.

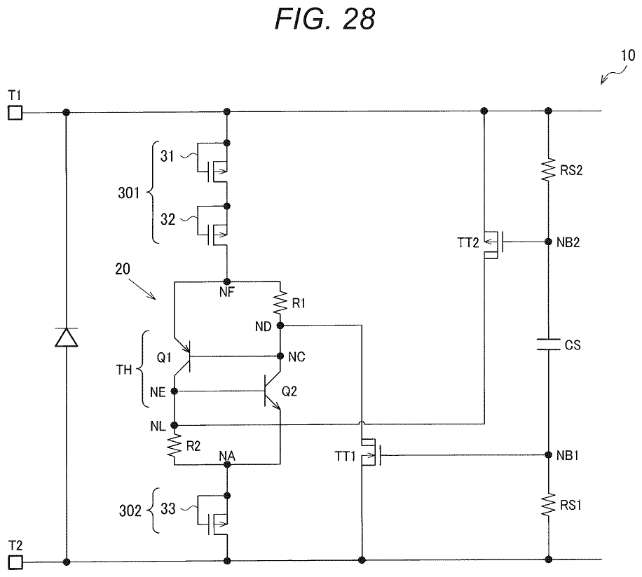

The circuit device 10 of the embodiment may be implemented as a configuration example illustrated in FIG. 28. The configuration in FIG. 28 is different from that in FIG. 26 in that the gates of the first trigger transistor TT1 and the second trigger transistor TT2 are driven by one predetermined capacitor CS.

FIG. 29 is a diagram illustrating an operation occurring when an ESD surge is applied to the circuit device 10 illustrated in FIG. 28. It is assumed that the potential of the first terminal T1 increases to, for example, 40 V. At this time, the potential of the node NB1 increases due to the capacitive coupling of the predetermined capacitor CS. That is, the potential of the first trigger transistor TT1 on the gate side increases. Accordingly, since a potential difference occurs between the gate and the source of the first trigger transistor TTI, the first trigger transistor TT1 is turned on, and a current flows in a direction of an arrow indicated by A61. More accurately, the arrow A61 is directed in the order of the first terminal T1, the first voltage hold circuit 301, the node NF, the first resistor R1, the node ND, the drain of the first trigger transistor TT1, the source of the first trigger transistor TT1, and the second terminal T2. Due to the capacitive coupling of the predetermined capacitor CS, the potential of the node NB2 is maintained at a voltage immediately before application of the ESD surge. More specifically, although the voltage between the source and the drain of the second trigger transistor TT2 is 40 V, a time constant of the RC circuit is set sufficiently large, and the potential of the node NB2 is maintained as a low level until the time corresponding to the time constant elapses. Accordingly, the second trigger transistor TT2 is on, and a current flows as indicated by an arrow A71. More accurately, the arrow A71 is directed in the order of the first terminal T1, the source of the second trigger transistor TT2, the drain of the second trigger transistor TT2, the node NL, the second resistor R2, the node NA, the second voltage hold circuit 302, and the second terminal T2.

Accordingly, a current flows through the first resistor R1 and the potential of the node ND coupled to the base of the transistor Q1 is lower than the potential of the node NF, and a current flows through the second resistor R2 and the potential of the node NE coupled to the base of the transistor Q2 is higher than the potential of the node NA. Accordingly, a current flows in a direction of an arrow indicated by A62, and a current flows in a direction of an arrow indicated by A72. More accurately, the arrow indicated by A62 is directed in the order of the first terminal T1, the first voltage hold circuit 301, the node NF, the emitter of the transistor Q1, the base of the transistor Q1, the node NC, the node ND, the drain of the first trigger transistor TTI, the source of the first trigger transistor TTI, and the second terminal T2. More accurately, the arrow indicated by A72 is directed in the order of the first terminal T1, the source of the second trigger transistor TT2, the drain of the second trigger transistor TT2, the node NL, the node NE, the base of the transistor Q2, the emitter of the transistor Q2, the node NA, the second voltage hold circuit 302, and the second terminal T2.

Accordingly, a current flows in a direction of an arrow indicated by A63, and a current flows in a direction of an arrow indicated by A73. More accurately, the arrow indicated by A63 is directed in the order of the first terminal T1, the first voltage hold circuit 301, the node NF, the emitter of the transistor Q1, the collector of the transistor Q1, the second resistor R2, the node NA, the second voltage hold circuit 302, and the second terminal T2. More accurately, the arrow A73 is directed in the order of the first terminal T1, the first voltage hold circuit 301, the node NF, the first resistor R1, the collector of the transistor Q2, the emitter of the transistor Q2, the node NA, the second voltage hold circuit 302, and the second terminal T2. That is, the thyristor TH is on.

As described above, in the circuit device 10 in FIG. 28, similarly to that in FIG. 26, the number of operation steps from a timing at which the ESD surge current flows to a timing at which the thyristor TH is on is four, that is, a step in which the potential of the first terminal T1 or the like increases, a step in which the currents indicated by the arrows A61 and A71 are generated, a step in which the currents indicated by the arrows A62 and A72 are generated, and a step in which the currents indicated by the arrows A63 and A73 are generated. That is, by implementing the circuit device 10 in FIG. 28, it is possible to shorten the time required from the timing at which the ESD surge current flows to the timing at which the thyristor TH is on, and to reduce the number of capacitors for functioning as the circuit device 10. Accordingly, the chip area related to the circuit device 10 can be reduced.

As described above, the circuit device of the embodiment includes a first terminal, a second terminal, a thyristor circuit, a voltage hold circuit, a trigger transistor, a predetermined capacitor, and a predetermined resistor. The thyristor circuit is provided between the first terminal and a first node. The voltage hold circuit is provided between the first node and the second terminal. The trigger transistor causes a trigger current to flow through the thyristor circuit. The predetermined capacitor is provided between the first terminal and a gate of the trigger transistor. The predetermined resistor is provided between the gate of the trigger transistor and the second terminal.

In this way, it is possible to construct an electrostatic protection circuit in which a voltage range for driving an internal circuit between the first terminal and the second terminal is wide and for which the manufacturing process can be made common. Since the circuit device of the embodiment does not require a transistor having a high gate breakdown voltage, the manufacturing process can be made common, and an increase in manufacturing cost can be prevented.

The voltage hold circuit may include a plurality of hold elements coupled in series, and a coupling node between an n-th hold element and an (n+1)-th hold element among the plurality of hold elements may be coupled to the gate of the trigger transistor.

In this way, the gate and a source of the trigger transistor are protected from an overvoltage, and it is possible to prevent an increase in chip area related to the circuit device.

The trigger transistor may be a transistor having a DMOS structure.

In this way, the trigger transistor can be provided in the circuit device that is driven at a high voltage.

The trigger transistor may be a transistor having the DMOS structure of a first conductivity type or a transistor having the DMOS structure of a second conductivity type, and an anode region of the thyristor circuit and a source region and a drain region of the DMOS structure of the second conductivity type may be second conductivity type impurity diffusion regions of a same layer.

In this way, the anode region can be formed together with the DMOS of the second conductivity type.

A cathode region of the thyristor circuit and a region for setting a potential of a substrate of a transistor having the DMOS structure of a second conductivity type may be a same first conductivity type impurity diffusion region.

In this way, the cathode region can be formed together with the DMOS of the second conductivity type.

The first terminal may be one of a high-potential-side power supply terminal and a low-potential-side power supply terminal, and the second terminal may be the other of the high-potential-side power supply terminal and the low-potential-side power supply terminal.

In this way, the thyristor circuit and the voltage hold circuit can be arranged between the high-potential-side power supply terminal and the low-potential-side power supply terminal.

The circuit device may further include a second voltage hold circuit provided between the first terminal and the thyristor circuit.

In this way, a trigger transistor having a low breakdown voltage between the source and the drain can be used in the circuit device.

The predetermined capacitor may be a MOM capacitor.

In this way, the manufacturing process for the predetermined capacitor and the manufacturing process for the other transistors can be made common.

The MOM capacitor may include a first electrode that is provided at a first metal layer and has a comb tooth shape in a plan view, and a second electrode that is provided at a second metal layer, faces the first electrode, and has a comb tooth shape in a plan view.

In this way, it is possible to increase the electrostatic capacitance of the predetermined capacitor while preventing an increase in chip area related to the predetermined capacitor.

The circuit device may include a gate protection circuit provided between the gate of the trigger transistor and the second terminal.

In this way, the gate and the source of the trigger transistor can be protected from an overvoltage.

The thyristor circuit may include an anode region of a second conductivity type, a cathode region of a first conductivity type, a first gate region of the first conductivity type, and a second gate region of the second conductivity type. The anode region of the second conductivity type may be provided at a first well of the first conductivity type and may be electrically coupled to the first terminal. The cathode region of the first conductivity type may be provided at a second well of the second conductivity type and may be electrically coupled to the second terminal. The first gate region of the first conductivity type may be provided at the first well and may be electrically coupled to the first terminal via a first resistor having one end coupled to the first terminal. The second gate region of the second conductivity type may be provided at the second well and may be electrically coupled to the second terminal via a second resistor. The trigger transistor may be provided between the other end of the first resistor in the thyristor circuit and the second terminal.

In this way, when the trigger transistor is on, a potential of a node coupled to the first gate region can be increased to cause a current to flow through the first gate region. Accordingly, a transistor related to the first gate region is on, and a transistor related to the second gate region can be turned on. Accordingly, the thyristor can be turned on.

Although the embodiment has been described in detail above, those skilled in the art could easily understand that many modifications can be made without substantially departing from the novel matters and the effects of the disclosure. Therefore, all such modifications are included in the scope of the present disclosure. For example, a term described at least once together with a different term having a broader meaning or the same meaning in the specification or the drawings can be replaced with the different term at any place in the specification or the drawings. All combinations of the embodiment and the modifications are also included in the scope of the present disclosure. The configurations, operations, and the like of the circuit device are not limited to those described in the embodiment, and various modifications can be made.

What is claimed is:

1. A circuit device comprising:
a first terminal;
a second terminal;
a thyristor circuit provided between the first terminal and a first node;
a voltage hold circuit provided between the first node and the second terminal;
a trigger transistor configured to cause a trigger current to flow through the thyristor circuit;
a predetermined capacitor provided between the first terminal and a gate of the trigger transistor; and
a predetermined resistor provided between the gate of the trigger transistor and the second terminal.

2. The circuit device according to claim 1, wherein
the voltage hold circuit includes a plurality of hold elements coupled in series, and a coupling node between an n-th hold element and an (n+1)-th hold element among the plurality of hold elements is coupled to the gate of the trigger transistor.

3. The circuit device according to claim 1, wherein
the trigger transistor is a transistor having a DMOS structure.

4. The circuit device according to claim 3, wherein
the trigger transistor is a transistor having the DMOS structure of a first conductivity type or a transistor having the DMOS structure of a second conductivity type, and
an anode region of the thyristor circuit and a source region and a drain region of the DMOS structure of the second conductivity type are second conductivity type impurity diffusion regions of a same layer.

5. The circuit device according to claim 3, wherein
a cathode region of the thyristor circuit and a region for setting a potential of a substrate of a transistor having the DMOS structure of a second conductivity type are a same second conductivity type impurity diffusion region.

6. The circuit device according to claim 1, wherein
the first terminal is one of a high-potential-side power supply terminal and a low-potential-side power supply terminal, and
the second terminal is the other of the high-potential-side power supply terminal and the low-potential-side power supply terminal.

7. The circuit device according to claim 1, further comprising:
a second voltage hold circuit provided between the first terminal and the thyristor circuit.

8. The circuit device according to claim 1, wherein
the capacitor is a MOM capacitor.

9. The circuit device according to claim 8, wherein
the MOM capacitor includes
a first electrode that is provided at a first metal layer and has a comb tooth shape in a plan view, and
a second electrode that is provided at a second metal layer, faces the first electrode, and has a comb tooth shape in a plan view.

10. The circuit device according to claim 1, further comprising:
a gate protection circuit provided between the gate of the trigger transistor and the second terminal.

11. The circuit device according to claim 1, wherein
the thyristor circuit includes
an anode region of a second conductivity type that is provided at a first well of a first conductivity type and is electrically coupled to the first terminal,
a cathode region of the first conductivity type that is provided at a second well of the second conductivity type and is electrically coupled to the second terminal,
a first gate region of the first conductivity type that is provided at the first well and is electrically coupled to the first terminal via a first resistor having one end coupled to the first terminal, and
a second gate region of the second conductivity type that is provided at the second well and is electrically coupled to the second terminal via a second resistor, and
the trigger transistor is provided between the other end of the first resistor in the thyristor circuit and the second terminal.
